(19) United States
(12) Patent Application Publication
(10) Pub. No.: US 2011/0244666 A1
(43) Pub. Date: Oct. 6, 2011

(54) Methods Of Manufacturing Stair-Type Structures And Methods Of Manufacturing Nonvolatile Memory Devices Using The Same

(75) Inventors: Ha-Na Kim, Seoul (KR); Gyungjin Min, Seongnam-si (KR); Chulho Shin, Yongin-si (KR); Sukho Joo, Seoul (KR); Han Geun Yu, Seoul (KR); Yeonghun Han, Hwaseong-si (KR)

(73) Assignee: SAMSUNG ELECTRONICS CO., LTD., Suwon-si (KR)

(21) Appl. No.: 13/080,288

(22) Filed: Apr. 5, 2011

(30) Foreign Application Priority Data
Apr. 5, 2010 (KR) 1020100031073

(51) Int. Cl. H01L 21/302; H01L 21/28; H01L 21/31

(52) U.S. Cl. 438/478; 438/695; 438/669; 438/587; 438/761; 257/E21.214; 257/E21.158; 257/E21.24

(57) ABSTRACT

Methods of manufacturing stair-type structures and methods of manufacturing nonvolatile memory devices using the same. Methods of manufacturing stair-type structures may include forming a plurality of thin layers stacked in plate shapes, forming a mask on an utmost thin layer, patterning the utmost layer using the mask as an etch mask, escalating a width of the mask and etching each of the thin layers at a different width of the mask to form a stair-type structure of the thin layers. Control gates may be formed into the stair-type structures using the methods of manufacturing stair-type structures.

### CROSS-REFERENCE TO RELATED APPLICATION

This U.S. non-provisional patent application claims priority under 35 U.S.C. §119 to Korean Patent Application No. 10-2010-0031073, filed on Apr. 5, 2010, in the Korean Intellectual Property Office (KIPO), the entire contents of which are hereby incorporated by reference.

### BACKGROUND

1. Field

Example embodiments of the inventive concepts relate to methods of manufacturing semiconductor devices, and more particularly, to methods of manufacturing stair-type structures and methods of manufacturing nonvolatile semiconductor devices using the same.

2. Description of the Related Art

The integration density of conventional 2-dimensional memory devices usually depends on the area of a unit memory cell. The integration density of the memory device depends on how the patterns are formed. The integration density of 2-dimensional memory devices is restrictively increased because the miniaturization of patterns generally requires high cost equipment. For overcoming limitations of 2-dimensional memory devices, 3-dimensional semiconductor memory devices which have memory cells arranged in 3-dimensions have been introduced. An example of a 3-dimensional memory device is a vertical NAND-flash memory device.

### SUMMARY

Example embodiments of the inventive concepts may provide methods for manufacturing nonvolatile memory devices. Example embodiments of the inventive concepts may also provide methods of manufacturing nonvolatile memory devices with a stair-type gate.

Example embodiments of the inventive concepts may include a method for forming a stair-type structure, including stacking a plurality of plate shaped thin layers, forming a mask on the utmost thin layer, patterning the utmost layer using the mask as an etch mask, escalating width of the mask and etching each of remained thin layers with escalating the width of the mask to form a stair-type structure of the thin layers.

In some example embodiments of the inventive concepts, the escalating the width of the mask may include forming a pre-spacer layer to cover the mask and spacer etching the pre-spacer layer to form a spacer on the sidewall of the mask. In other example embodiments of the inventive concepts, the forming of the pre-spacer layer may include providing a gas including deposition elements and etching elements to deposit a polymer layer which covers the mask. In still other example embodiments of the inventive concepts, the spacer etching may include providing the gas to remove a portion of the polymer layer such that the spacer is formed on at least one of the sidewalls of the mask.

In even other example embodiments of the inventive concepts, the depositing of the pre-spacer layer may include providing a first gas in which the deposition elements are more plenty than the etching elements. In yet other example embodiments of the inventive concepts, the spacer etching may include providing a second gas in which the etching elements are more plenty than the deposition elements. The depositing of the pre-spacer layer and the spacer etching may be performed in-situ. In further example embodiments of the inventive concepts, the deposition element may include carbon or carbon/hydrogen, and the etching element comprises fluorine.

In still further example embodiments of the inventive concepts, the first gas may include methyl fluoride (CH3F), and the second gas comprises triple fluoric methane (CHF3) or carbon tetra fluoride (CF4). In even further example embodiments of the inventive concepts, the second gas may further include oxygen (O2). In yet further example embodiments of the inventive concepts, the forming of the plurality of the thin layers may include forming at least two different, layers alternately to form a plurality of the thin layers.

Embodiments of the inventive concepts may further provide a method for forming a stair-shaped structure, including stacking a plurality of plate shaped conductive layers, forming a mask on the utmost conductive layer, etching the utmost conductive layer using the mask as an etch mask, providing a gas including deposition elements and etching elements to deposit a polymer layer which covers the mask. According to example embodiments the deposition elements may be more plenty than the etching elements, the gas in which the etching elements are more plenty than the deposition elements are provided such that the polymer layer is deformed into a polymer spacer on the mask, the depositing of the polymer layer and the deforming of the polymer layer may be alternately performed to escalating the mask and each of remained conductive layers may be patterned with escalating the width of the mask.

In some example embodiments of the inventive concepts, the polymer spacer may be formed on a sidewall, either sidewalls or four sidewalls of the mask. In other example embodiments of the inventive concepts, the forming of the mask may include at least one of a first photoresist pattern, a second photoresist pattern and a third photoresist pattern. The first photoresist pattern may cross over the center of the utmost conductive layer, the second photoresist pattern may cover a side portion of the top surface of the utmost conductive layer, and the third photoresist pattern may be limited on the center portion of the utmost conductive layer.

In still other example embodiments of the inventive concepts, the polymer spacer may be formed on both sidewalls of the first photoresist pattern such that the stair-type structure is formed at both sides of the conductive layers. In even other example embodiments of the inventive concepts, the polymer spacer may be formed on a sidewall of the second photoresist pattern such that the stair-type structure is formed at a sidewall of the conductive layers. In yet other example embodiments of the inventive concepts, the polymer spacer may be formed on four sidewalls of the third photoresist pattern such that the stair-type structure is at four sides of the conductive layers.

In further example embodiments of the inventive concepts, the depositing of the polymer layer may be performed by a deposition process using plasma. The plasma may include argon (Ar), nitrogen (N2) and methyl fluoride (CH3F) which includes carbon as the deposition element and fluorine as the etching element. In still further example embodiments of the inventive concepts, the deforming of the polymer spacer may be performed by a dry etching process using plasma. The plasma in the etching process may include argon (Ar), nitrogen (N2), oxygen (O2) and trifluoromethane (CHF3) or carbon tetrafluoride (CF4) which includes carbon as the deposition element and fluorine as the etching element. The depositing of the polymer layer and the deforming of the polymer layer may be performed in-situ.

In even further example embodiments of the inventive concepts, the method may further include forming plate shaped insulating layers between the conductive layers. Each of the plate shaped insulating layers may be etched using the escalated mask to form a stair-type structure of the insulating layer.

Example embodiments of the inventive concepts may still further provide a method of manufacturing a nonvolatile memory device, including forming a lower selection gate on a semiconductor substrate, forming a plurality of the control gates in a stair-type structure on the lower selection gate, forming an upper selection gate on the control gates and fowling an active pillar connected to the semiconductor substrate through the gates. The forming of the control gates may include stacking a plurality of plate shaped control gates, forming a mask on the utmost control gate, patterning the utmost control gate using the mask as an etch mask, escalating width of the mask and patterning each of remained control gates with escalating the width of the mask to form a stair-type structure of the control gates such that a portion of each control gate is defined as a word line pad.

In some example embodiments of the inventive concepts, escalating the width of the mask width may include providing a gas including deposition elements and etching elements to deposit a polymer layer which covers the mask and providing the gas to remove a portion of the polymer layer to form a polymer spacer on at least one sidewall of the mask. In other example embodiments of the inventive concepts, the forming of the polymer spacer may be performed in-situ with the depositing of the polymer layer. The quantities ratio of the deposition elements and the etching elements may be different in the depositing of the polymer layer and in the etching of the polymer layer.

In still other example embodiments of the inventive concepts, the deposition elements may be provided more plenty than the etching elements in the depositing of the polymer layer, and the etching elements may be provided more plenty than the deposition elements in the etching of the polymer layer. In even other example embodiments of the inventive concepts, the deposition element comprises carbon (C), and the etching element comprises fluorine (F). In yet other example embodiments of the inventive concepts, the depositing of the polymer layer may be performed by a deposition process using plasma. The plasma may include argon (Ar), nitrogen (N2) and methyl fluoride (CH3F) which includes carbon as the deposition element and fluorine as the etching element.

In further example embodiments of the inventive concepts, the forming of the polymer spacer may be performed by a dry etching process using plasma. The plasma in the etching process may include argon (Ar), nitrogen (N2), and trifluoromethane (CHF3) or carbon tetrafluoride (CF4) which includes carbon as the deposition element and fluorine as the etching element. In still further example embodiments of the inventive concepts, the plasma in the etching process may further include oxygen (O2).

Example embodiments of the inventive concepts may even further provide a method of manufacturing a nonvolatile memory device, including alternately stacking plate shaped insulating layers and plate shaped sacrificial layers on a semiconductor substrate to fowl a thin layers structure, forming a mask on the thin layers structure, escalating width of the mask, patterning each of the thin layers with escalating the width of the mask to from a stair-type structure of the thin layers. Each of the thin layers may be etched using the escalated mask as an etch mask, the sacrificial layers may be selectively removed to form recess regions between the insulating layers, respectively, and the recess regions may be filled with conductive layers to form gates which are stacked in stair-type structure.

In some example embodiments of the inventive concepts, the escalating the width of the mask may include providing a gas including deposition elements and etching elements to form a polymer layer which covers the mask and etching the polymer layer in-situ with the depositing of the polymer layer to form a polymer spacer at least one sidewall of the mask. The deposition elements may be provided more plenty than the etching elements in the depositing of the polymer layer and the etching elements may be provided more plenty than the deposition elements in the etching of the polymer layer.

In other example embodiments of the inventive concepts, the depositing of the polymer layer may be performed using plasma which includes methyl fluoride (CH3F) and the etching of the polymer layer may be performed using plasma which includes trifluoromethane (CHF3) or carbon tetrafluoride (CF4). In still other example embodiments of the inventive concepts, the forming of the recess regions may include removing a portion of the thin layers structure to form a trench in which the semiconductor substrate or the lowermost insulating layer is exposed and providing an etchant to the thin layers structure through the trench to selectively remove the sacrificial layers.

Example embodiments of the inventive concepts may yet further provide a method of manufacturing a stair type structure including stacking a plurality of thin layers, forming a mask on the plurality of thin layers, patterning at least one of the plurality of thin layers using the mask as an etch mask, sequentially increasing a width of the mask and patterning a different one of the plurality of thin layers such that each of the plurality of thin layers is patterned using a different width of the mask, the patterned plurality of thin layers forming a stair-type structure.

Example embodiments of the inventive concepts may yet still further provide a method of manufacturing a stair type structure including stacking a plurality of conductive layers, forming a mask on the plurality of conductive layers, depositing a polymer layer to cover the mask by providing a gas including at least one deposition element and at least one etching element, an atomic ratio of the at least one deposition element to the at least one etching element being greater than 1, transforming the polymer layer into a polymer spacer by providing a gas including the at least one deposition element and the at least one etching element, an atomic ratio of the at least one etching element to the at least one deposition element being greater than 1, sequentially performing the depositing of the polymer layer and the transforming of the polymer layer a plurality of times to sequentially increase a width of the mask and patterning each of the plurality of conductive layers using a different width of the mask.

Example embodiments of the inventive concepts may yet still further provide a method of manufacturing a nonvolatile memory device including forming a lower selection gate on a semiconductor substrate, forming a plurality of control gates in a stair-type structure on the lower selection gate, the forming of the plurality of control gates including stacking a plurality control gate layers, forming a mask on the plurality of control gate layers, patterning a one of the plurality of control gate layers closest to the mask by using the mask as an etch mask, and patterning each of the control gate layers after the control gate layer closest to the mask by sequentially increasing a width of the mask, each of the plurality of control gate layers patterned using a different width of the mask, the patterning of the control gate layers forming the stair-type structure such that a portion of each of the plurality of control gates is a word line pad, forming an upper selection gate on the plurality of control gates and forming an active pillar penetrating through the plurality of control gates, the active pillar formed to connect to the semiconductor substrate.

Example embodiments of the inventive concepts may yet still even further provide a method of manufacturing a nonvolatile memory device including alternately stacking a plurality of insulating layers and a plurality of sacrificial layers on a semiconductor substrate to form a thin layer structure including a plurality of thin layers, forming a mask on the thin layer structure, patterning each of the plurality of thin layers by sequentially increasing a width of the mask so that each of the plurality of thin layers is etched using the mask at a different width as an etch mask, the patterning of the plurality of thin layers forming a stair-type structure, selectively removing the plurality of sacrificial layers to form a plurality of recess regions between the insulating layers and filling the recess regions with conductive layers to form gates stacked in the stair-type structure.

Example embodiments of the inventive concepts may provide a patterning method including stacking a plurality of layers, forming a first mask on the plurality of layers, patterning a first layer of the plurality of layers using the first mask, increasing a width of the first mask to form a second mask and patterning a second layer of the plurality of layers using the second mask.

### BRIEF DESCRIPTION OF THE DRAWINGS

Example embodiments will be more clearly understood from the following brief description taken in conjunction with the accompanying drawings. FIGS. 1A-10B represent non-limiting, example embodiments of the inventive concepts as described herein.

FIG. 1A is a perspective view illustrating nonvolatile memory devices according to example embodiments of the inventive concepts;

FIG. 1B is a perspective view illustrating a cell region of FIG. 1A;

FIGS. 1C and 1D are perspective views illustrating a memory transistor of FIG. 1B;

FIG. 1E is a circuit diagram according to example embodiments of the inventive concepts;

FIGS. 2A-2H are perspective views illustrating methods of manufacturing nonvolatile memory devices according to example embodiments of the inventive concepts;

FIGS. 3A-3L are perspective views illustrating methods of manufacturing stair-type structures according to example embodiments of the inventive concepts;

FIG. 4A is a perspective view illustrating nonvolatile memory devices according to another example embodiment of the inventive concepts;

FIGS. 4B and 4C are perspective views illustrating methods for fowling a stair-type structure of a nonvolatile memory device according to example embodiments of the inventive concepts;

FIG. 5A is a perspective view illustrating nonvolatile memory devices according to example embodiments of the inventive concepts;

FIGS. 5B and 5C are perspective views illustrating methods of manufacturing a stair-type structure of nonvolatile memory devices according to example embodiments of the inventive concepts;

FIGS. 6A-6M are perspective views illustrating methods of manufacturing nonvolatile memory devices according to example embodiments of the inventive concepts;

FIGS. 7A-7E are perspective views illustrating nonvolatile memory devices according to example embodiments of the inventive concepts;

FIGS. 8A-8D are perspective views illustrating methods of manufacturing stair-type gates of the nonvolatile memory device according to example embodiments of the inventive concepts;

FIGS. 9A-9G are perspective views illustrating methods of manufacturing nonvolatile memory devices according to example embodiments of the inventive concepts;

FIG. 10A is a block diagram illustrating memory cards including nonvolatile memory devices according to example embodiments of the inventive concepts; and

FIG. 10B is a block diagram of information processing systems including nonvolatile memory devices according to example embodiments of the inventive concepts.

It should be noted that these figures are intended to illustrate the general characteristics of methods, structure and/or materials utilized in certain example embodiments of the inventive concepts and to supplement the written description provided below. These drawings are not, however, to scale and may not precisely reflect the precise structural or performance characteristics of any given embodiment, and should not be interpreted as defining or limiting the range of values or properties encompassed by example embodiments. For example, the relative thicknesses and positioning of molecules, layers, regions and/or structural elements may be reduced or exaggerated for clarity. The use of similar or identical reference numbers in the various drawings is intended to indicate the presence of a similar or identical element or feature.

### DETAILED DESCRIPTION

Example embodiments of the inventive concepts will now be described more fully with reference to the accompanying drawings, in which example embodiments are shown. Example embodiments of the inventive concepts may, however, be embodied in many different forms and should not be construed as being limited to the embodiments set forth herein; rather, these embodiments are provided so that this disclosure will be thorough and complete, and will fully convey the concept of example embodiments to those of ordinary skill in the art. In the drawings, the thicknesses of layers and regions are exaggerated for clarity. Like reference numerals in the drawings denote like elements, and thus their description will be omitted.

It will be understood that when an element is referred to as being “connected” or “coupled” to another element, it can be directly connected or coupled to the other element or intervening elements may be present. In contrast, when an element is referred to as being “directly connected” or “directly coupled” to another element, there are no intervening elements present. Like numbers indicate like elements throughout. As used herein the term “and/or” includes any and all combinations of one or more of the associated listed items. Other words used to describe the relationship between elements or layers should be interpreted in a like fashion (e.g., “between” versus “directly between,” “adjacent” versus “directly adjacent,” “on” versus “directly on”).

It will be understood that, although the terms “first”, “second”, etc. may be used herein to describe various elements, components, regions, layers and/or sections, these elements, components, regions, layers and/or sections should not be limited by these terms. These terms are only used to distinguish one element, component, region, layer or section from another element, component, region, layer or section. Thus, a first element, component, region, layer or section discussed below could be termed a second element, component, region, layer or section without departing from the teachings of example embodiments of the inventive concepts.

Spatially relative terms, such as “beneath,” “below,” “lower,” “above,” “upper” and the like, may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features. Thus, the exemplary term “below” can encompass both an orientation of above and below. The device may be otherwise oriented (rotated 90 degrees or at other orientations) and the spatially relative descriptors used herein interpreted accordingly.

The terminology used herein is for the purpose of describing particular example embodiments only and is not intended to be limiting of example embodiments of the inventive concepts. As used herein, the singular forms “a,” “an” and “the” are intended to include the plural forms as well, unless the context clearly indicates otherwise. It will be further understood that the terms “comprises”, “comprising”, “includes” and/or “including,” if used herein, specify the presence of stated features, integers, steps, operations, elements and/or components, but do not preclude the presence or addition of one or more other features, integers, steps, operations, elements, components and/or groups thereof.

Example embodiments of the inventive concepts are described herein with reference to cross-sectional illustrations that are schematic illustrations of idealized embodiments (and intermediate structures) of example embodiments. As such, variations from the shapes of the illustrations as a result, for example, of manufacturing techniques and/or tolerances, are to be expected. Thus, example embodiments should not be construed as limited to the particular shapes of regions illustrated herein but are to include deviations in shapes that result, for example, from manufacturing. For example, an implanted region illustrated as a rectangle may have rounded or curved features and/or a gradient of implant concentration at its edges rather than a binary change from implanted to non-implanted region. Likewise, a buried region formed by implantation may result in some implantation in the region between the buried region and the surface through which the implantation takes place. Thus, the regions illustrated in the figures are schematic in nature and their shapes are not intended to illustrate the actual shape of a region of a device and are not intended to limit the scope of example embodiments.

Unless otherwise defined, all terms (including technical and scientific terms) used herein have the same meaning as commonly understood by one of ordinary skill in the art to which example embodiments belong. It will be further understood that terms, such as those defined in commonly-used dictionaries, should be interpreted as having a meaning that is consistent with their meaning in the context of the relevant art and will not be interpreted in an idealized or overly formal sense unless expressly so defined herein.

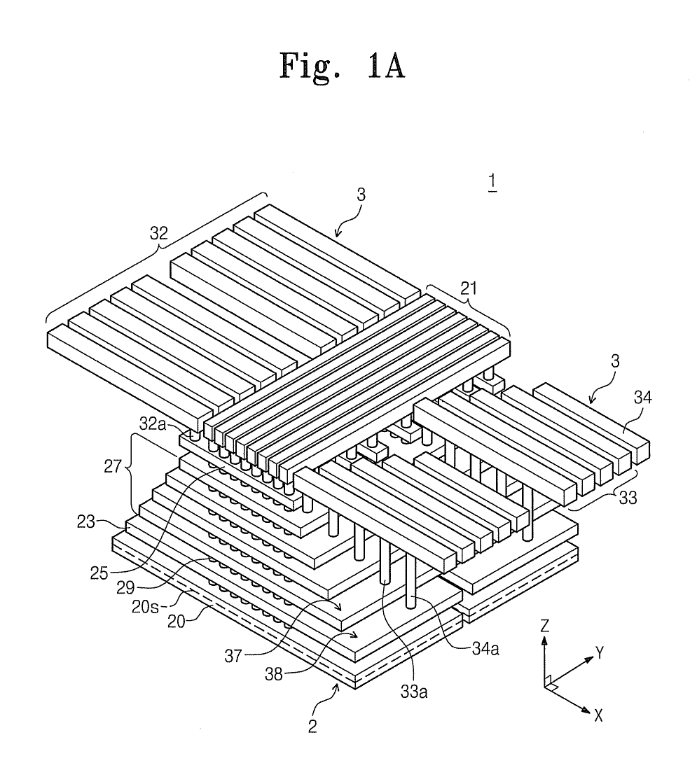

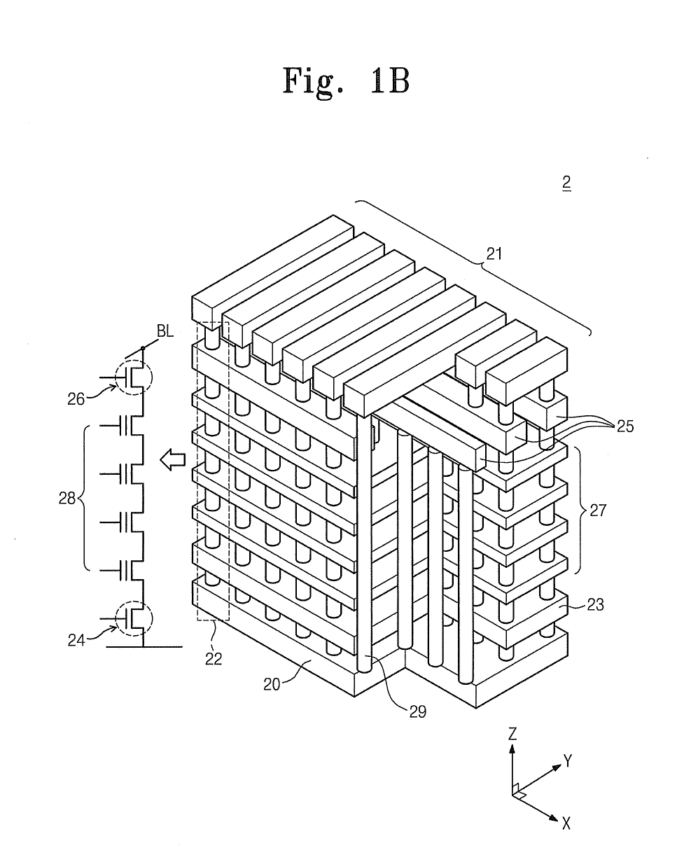

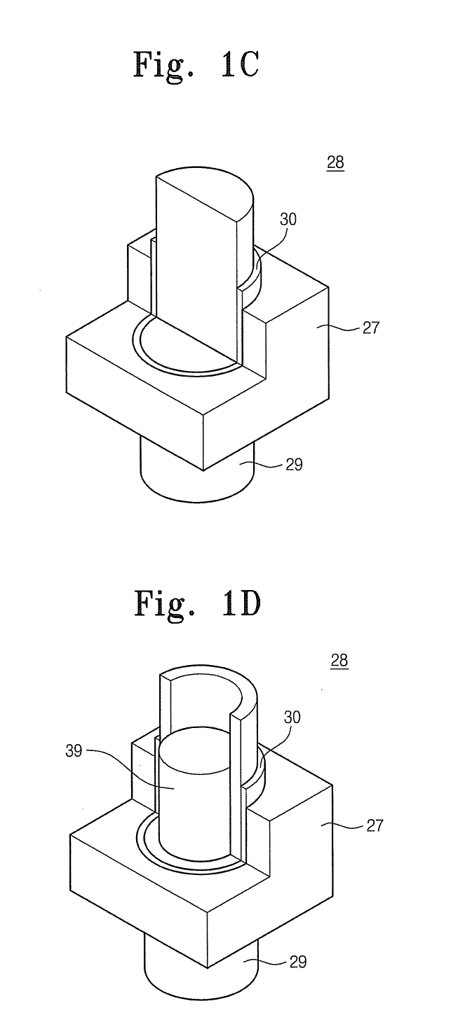

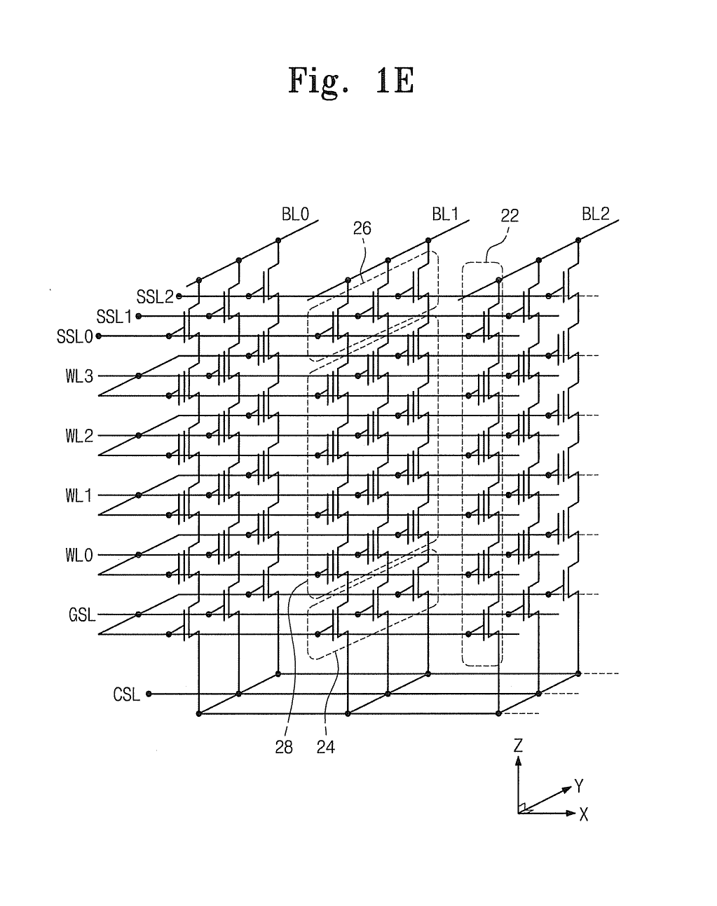

FIG. 1A is a perspective view illustrating nonvolatile memory devices according to example embodiments of the inventive concepts. Referring to FIG. 1A, a nonvolatile memory device 1 according to example embodiments of the inventive concepts may include a cell region 2 including memory cells and a peripheral region 3 including a peripheral circuit for driving the memory cells.

The cell region 2 may include a plurality of plate shaped control gates 27 on a semiconductor substrate 20, stacked in a Z-direction and extending in an X-Y plane, a lower selection gate 23 between the semiconductor substrate 20 and the control gates 27, a plurality of upper selection gates 25 which are on the control gates 27, a plurality of bit lines 21 on the upper selection gates 25 and extending in the Y direction, and a plurality of active pillars 29 on the semiconductor substrate 20 and extending in the Z-direction. Each of the active pillars 29 may extend from the semiconductor substrate 20 toward the bit line 21 and may penetrate the upper and lower selection gates 23 and 25, and the control gates 27. The active pillar 29 may be a channel. The semiconductor substrate 20 may be a P type silicon substrate. The active pillar 29 may be of identical or similar material as the semiconductor substrate 20 and may be the same conductivity type as the conductivity type of the semiconductor substrate 20. The semiconductor substrate 20 may include a source 20s of an opposite conductivity type (e.g., N type) to the semiconductor substrate 20.

The peripheral region 3 may include a plurality of first lines 32 which may connect a plurality of the upper selection gates 25 to an upper selection line driving circuit (not shown), a plurality of second lines 33 which may connect a plurality of the control gates 27 to a word line driving circuit (not shown), and a third line 34 which may connect the lower selection line 23 to a lower selection line driving circuit (not shown). A plurality of first contact plugs 32a may be between a plurality of the first lines 32 and a plurality of the upper selection gates 25 to electrically connect the first lines 32 to the upper selection gates 25. A plurality of second contact plugs 33a may be between a plurality of the second lines 33 and a plurality of the control gates 27 to electrically connect the second lines 33 to the control gates 27. A third contact plug 34a may be between the third line 34 and the lower selection gate 23 to electrically connect the third line 34 to the lower selection gate 23.

One of the lower selection gate 23 and the upper selection gate 25 may be plate shaped and parallel with the X-Y plane, and the other may be line shaped and extend in the X-direction. The lower selection gate 23 and the upper selection gate 25 may be line shaped and extend in the X-direction. According to example embodiments, the lower selection gate 23 may be plate shaped in an X-Y plane and the upper selection gate 23 may be line shaped and extend in the X-direction. The gates 23, 25 and 27 may be in a stair type structure. A plurality of word line pads 37 may electrically connect a plurality of the second contact plugs 33a to a plurality of the control gates 27, respectively. An exposed surface of a lower control gate 27 may be defined as a word line pad 37. A lower selection line pad 38 may electrically connect the third contact plug 34a to the lower selection gate 23. The stair type structure may be at both sides of the control gate 27.

FIG. 1B is a perspective view illustrating a cell region of FIG. 1A. FIGS. 1C and 1D are perspective views illustrating a memory transistor of FIG. 1B. Referring to FIG. 1B, the active pillars 29 and the control gates 27 may be included in memory transistors 28. The active pillars 29 and the lower selection gate 23 may be included in lower selection transistors 24. The active pillars 29 and the upper selection gates 25 may be included in upper selection transistors 26. The memory device 1 according to example embodiments of the inventive concepts may be a NAND flash memory device in which a plurality of the memory transistors 28 and the upper and lower transistors 24 and 26 along one active pillar 29 are connected in series to form a cell string 22. For example, one cell string 22 may include four memory transistors 28.

The number of the memory transistors 28 in the cell string 22 may be determined according to memory capacity (e.g., eight, sixteen and/or thirty two). The active pillar 29 may be a cylindrical pillar, a square pillar and/or other shaped pillar. It should be noted that although FIG. 1B illustrates one upper and one lower selection transistor, there may be more than one of each in a string. The memory transistors 28 and the upper and lower selection transistors 24 and 26 may be depletion transistors and the active pillars 29 may not include source/drains. The memory transistors 28 and the upper and lower transistors 24 and 26 may be enhancement transistors and the active pillars 29 may include source/drains. A plurality of the active pillars 29 may have axes in the Z-direction through a plurality of the control gates 27. Intersections of the control gates 27 and the active pillars 29 may be distributed in three dimensions. The memory transistors 28 may be at intersections between the active pillars 29 and the control gates 27.

Referring to FIG. 1C, a gate insulating layer 30 including a charge storage layer may be between an active pillar 29 and a control gate 27. The charge storage layer may include an insulating layer capable of trapping charges. For example, if the gate insulating layer 30 is an ONO layer which includes a silicon oxide layer, a silicon nitride layer, and/or a silicon oxynitride layer and a silicon oxide layer, charges may be trapped in the gate insulating layer 30 to be retained. The charge storage layer may include a floating gate which is formed of a conductive layer. Referring to FIG. 1D, the active pillar 29 may include an insulator 39 at the core. The insulator 39 may be pillar shaped. Because the insulator 39 is in the active pillar 29, the thickness of the active pillar 29 may be thinner than that of FIG. 1C. Trap sites of the carriers may be reduced. Referring to FIG. 1B, the upper and lower selection transistors 26 and 24 may be similar in structure to the transistors illustrated in FIG. 1C or 1D. The gate insulating layer 30 may be formed of a silicon oxide layer and/or a silicon nitride layer.

FIG. 1E is an equivalent circuit diagram according to example embodiments of the inventive concepts. Referring to FIGS. 1E and 1A, in the nonvolatile memory device 1 according to an example embodiment, the control gates 27 may correspond to word lines WL0˜WL3, the upper selection gates 25 may correspond to string selection lines SSL0˜SSL2, the lower selection gate 23 may correspond to a ground selection line GSL and the source 20s in the semiconductor substrate 20 may correspond to a common source line CSL. A plurality of the cell strings 22 may be connected to each bit line BL0˜BL2.

The control gates 27 may be planar in structure and may extend in two dimensions such that each of the word lines WL0˜WL3 may be also planar structure and substantially perpendicular to the cell string 22. A plurality of the memory transistors 28 may be connected with a plurality of the word lines WL0˜WL3 while being disposed in three dimensions. Because the upper selection gates 25 may extend in the X-direction to form interconnection structures separated from each other, a plurality of the string selection lines SSL0˜SSL2 may cross the bit lines BL0˜BL2 in the X-direction. Each of the cell strings 22 may be independently selected by selecting one of the string selection lines SSL0˜SSL2 and one of the bit lines BL0˜BL2.

Although example embodiments are described with 3 bit lines, 3 string selection lines and 4 word lines, example embodiments are not so limited. The number of bit lines, string selection lines and/or word lines may be determined according to, for example, a number of memory cells in a string and/or a number of strings. The lower gate 23 may be a planar structure and may extend in two dimensions such that the ground selection line GSL may have planar structure and may be substantially perpendicular to the cell string 22. The ground selection line GSL may control an electric connection between the active pillar 29 and the substrate 20.

In a program operation of the nonvolatile memory device 1 according to example embodiments, a voltage drop may be induced between a selected word line WL and a selected active pillar 29 to inject charges into the charge storage layer. For example, a program voltage may be applied to a selected word line WL such that a charge is injected from the active pillar 29 into a charge storage layer of a memory transistor 28 of a memory cell to be programmed. This charge injection may be performed by, for example, Fowler-Nordheim tunneling phenomenon. Because the program voltage applied to the selected word line WL may program a memory transistor 28 of a non-selected memory cell, boosting technology may be used to prevent non-selected memory transistor from being programmed.

In a read operation, zero voltage may be applied to a word line WL to which a selected memory transistor 28 is connected and a read voltage may be applied to other word lines. The charge in the bit line BL may be passed or not in accordance with a threshold voltage of the memory transistor 28. The data state of the memory transistor 28 may be determined by sensing the bit line potential.

An erase operation may be performed in a memory block by using GIDL (Gate Induced Drain Leakage). For example, an erase voltage may be applied to a selected bit line BL and the substrate 20 to pump up the potential of the active pillar 29. The GIDL is generated at a terminal of the lower selection gate 23 such that electrons generated by the GIDL are discharged into the substrate 20 and holes are discharged into the active pillar 29. Substantially the same potential as the erase voltage may be transferred to the active pillar 29 that is a channel of the memory transistor 28. If the potential of the word line WL is zero volts, electrons accumulated in the memory transistor 28 may be discharged to perform a data erase. Word lines in a non-selected block may be floated so as not to induce undesired erase. The operation of the non-volatile memory device according to example embodiments is not limited to the above but is described for purposes of illustration only.

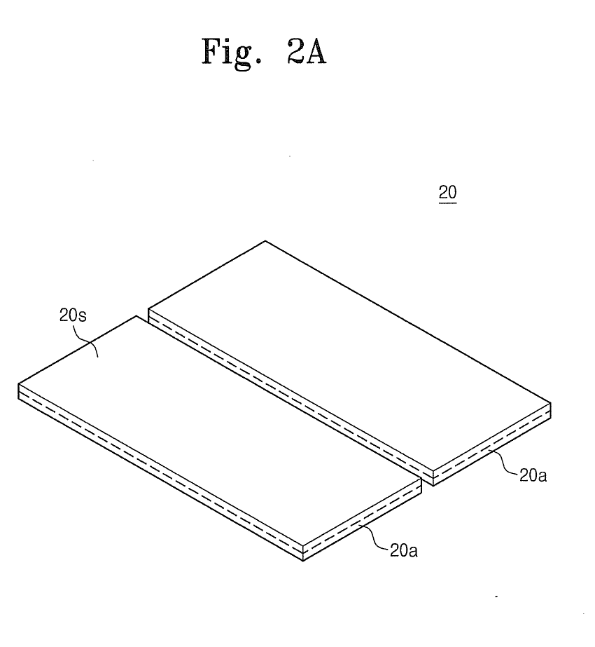

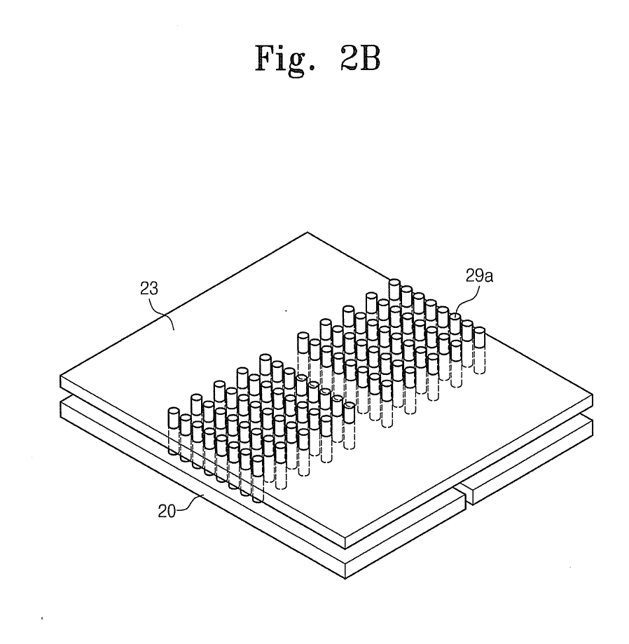

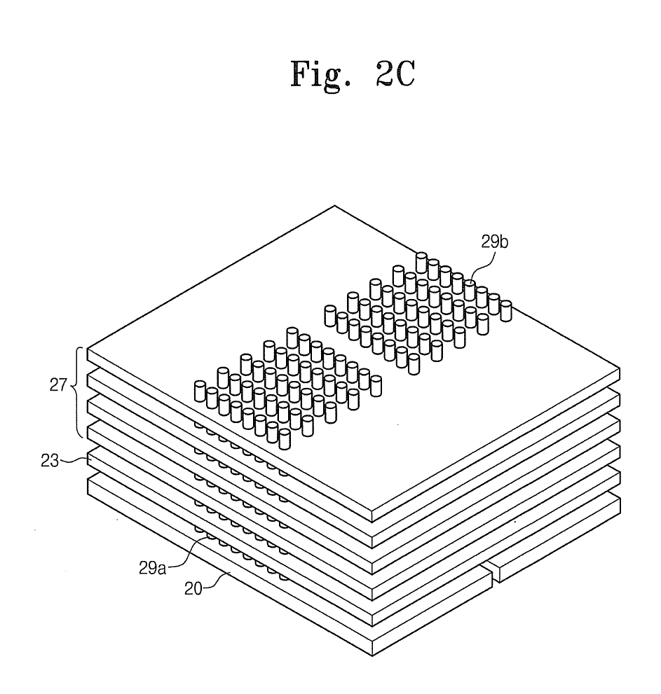

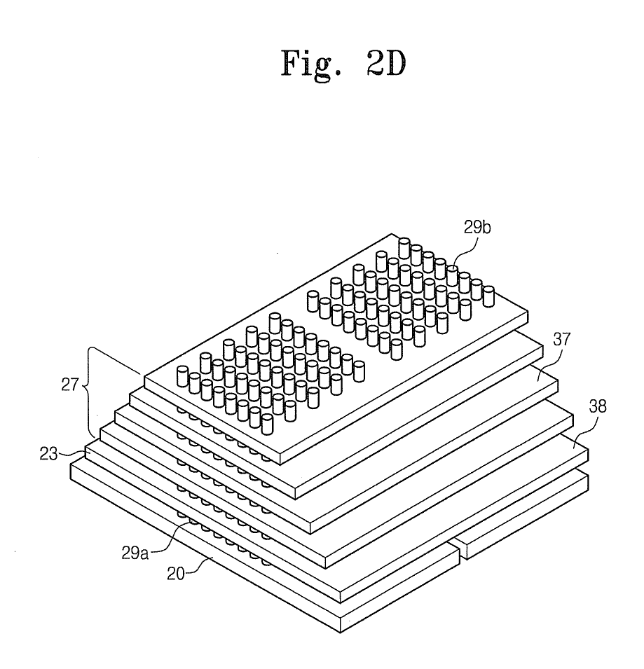

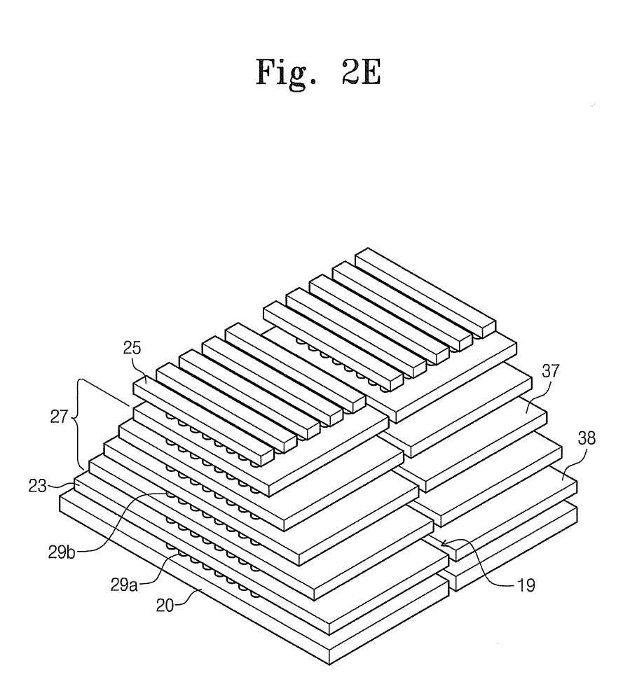

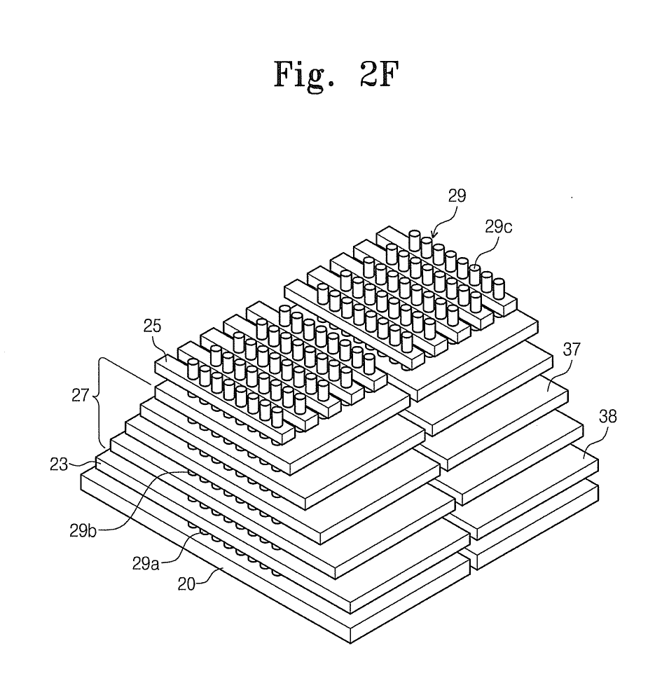

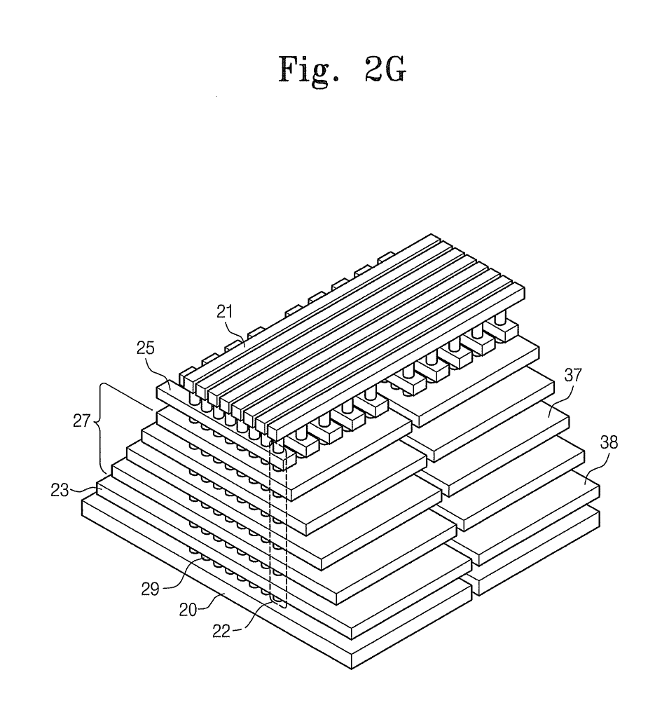

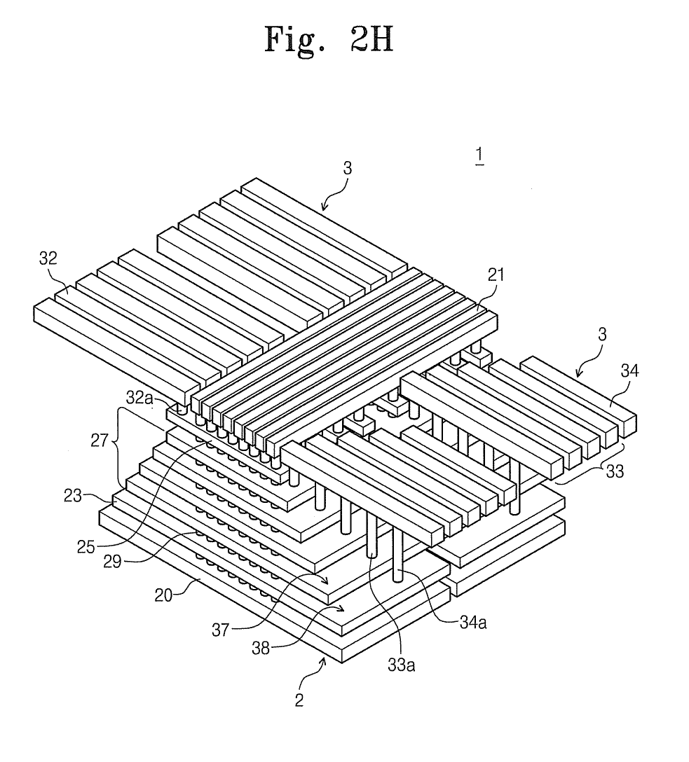

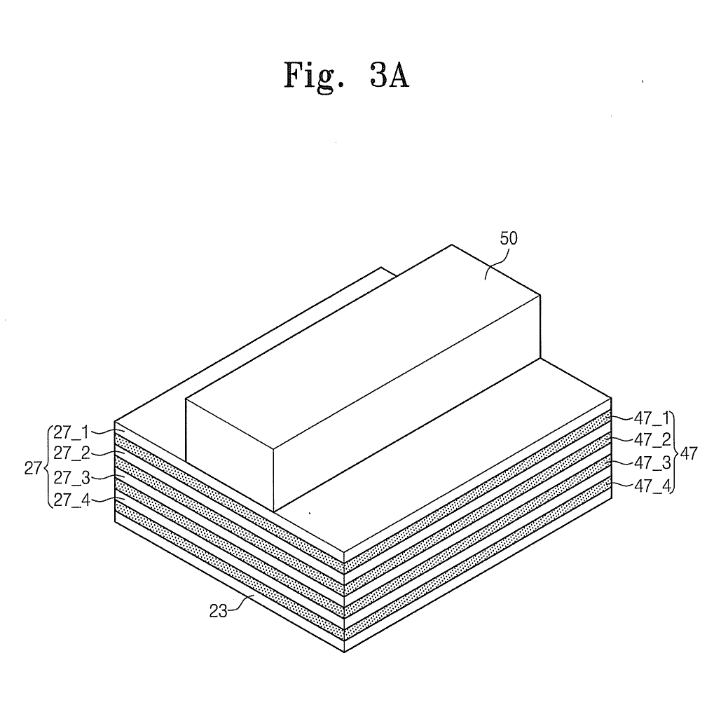

FIGS. 2A-2H are perspective views illustrating methods of manufacturing nonvolatile memory devices according to example embodiments of the inventive concepts. Referring to FIG. 2A, a semiconductor substrate 20 is provided. The semiconductor substrate 20 may be, for example, a P-type single crystalline silicon wafer. The semiconductor substrate 20 may include a device isolation layer to define an active region 20a. The active region 20a may include a source 20s. The source 20s may be, for example, N-type.

Referring to FIG. 2B, a lower selection gate 23 may be formed on the semiconductor substrate 20. The lower selection gate 23 may be formed of conductive material. The lower selection gate 23 may be formed of, for example, polycrystalline silicon and/or metal by deposition. The lower selection gate 23 may be formed into a plate shape and/or a line shape. According to an example embodiment, polycrystalline silicon may be deposited to form a plate shaped lower selection gate 23. A plurality of first pillars 29a may be formed in a deposition process and/or an epitaxial process. The first pillars 29a may penetrate the lower gate 23 to be electrically connected to the semiconductor substrate 20. The first pillars 29a may be formed by forming a hole through the lower selection gate 23 to expose the semiconductor substrate 20 and then filling the hole with conductive material (and/or one of the materials described above with respect to pillars). The etching may be performed by, for example, dry etching.

The first pillars 29a may have cylindrical, elliptical, polygonal and/or other cross-sectional shape. The first pillars 29a may be formed to include the same or similar material to the semiconductor substrate 20. For example, the first pillars 29a may be formed to include amorphous silicon, single crystalline silicon and/or polycrystalline silicon. A first gate insulating layer (not shown) may be formed between the first pillars 29a and the lower selection gate 23. The same structure as shown in FIG. 1C may be formed. The first gate insulating layer may be formed of a silicon oxide layer and/or a silicon nitride layer which is formed in, for example, a deposition process.

Referring to FIG. 2C, a plurality of control gates 27 may be formed on the lower selection gate 23. The control gates 27 may be formed of the same or similar material to the lower selection gate 23. For example, the control gates 27 may be formed into a plate shape by, for example, depositing polycrystalline silicon. The control gates 27 may each be formed to a same thickness. The control gates 27 may be of the same thickness as the lower selection gate 23 or not. A plurality of second pillars 29b may be formed in, for example, a deposition process and/or an epitaxial process such that the second pillars penetrate the control gates 27 to be connected with the first pillars 29a, respectively.

The second pillars 29b may be formed by fanning holes through the control gates 27 to expose the first pillars 29a and filling the holes with conductive material. The holes may be formed in, for example, a dry etch process. The second pillars 29b may be formed of the same or similar material as the first pillar 29a. For example, the second pillars 29b may be formed of single crystalline silicon and/or polycrystalline silicon. The second pillars 29b may be formed into a structure with a single crystalline silicon layer and/or polycrystalline silicon layer and an insulating layer in the silicon layer as shown in FIG. 1D. A second gate insulating layer (not shown) including a charge storage layer may be formed between the second pillars 29b and the control gate 27. The same or similar structure as shown in FIG. 1D may be formed.

The second gate insulating layer may be formed into a three layered structure of a silicon oxide layer, a silicon nitride and/or silicon oxynitride layer and a silicon oxide layer which are sequentially stacked. The silicon nitride and/or silicon oxynitride layer may be used as a charge storage layer in which charges are trapped to store information. One of the oxide layers may be a blocking insulating layer and the other may be a tunnel oxide layer. The charge storage layer may be formed into floating gate structure that is formed of, for example, polycrystalline silicon. The tunnel insulating layer may be formed of, for example, a silicon nitride and/or a silicon oxide/silicon nitride layer, and the blocking insulating layer may be formed of, for example, a silicon nitride layer, a silicon oxide/silicon nitride layer, an aluminum oxide and/or a combination thereof.

Referring to FIG. 2D, the control gates 27 may be formed in a stair type structure. A word line pad 37 may be defined on each control gate 27. On the lower selection gate 23, a lower selection line pad 38 may be formed because of the stair type structure.

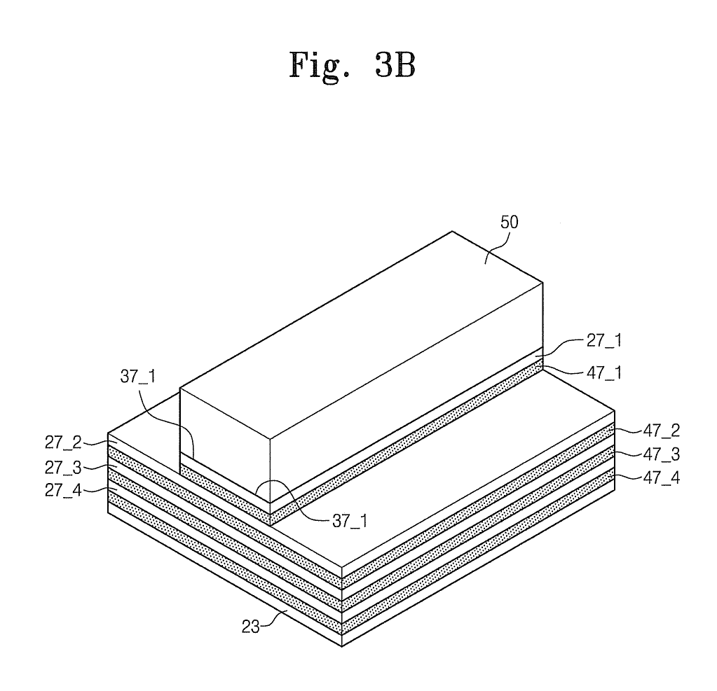

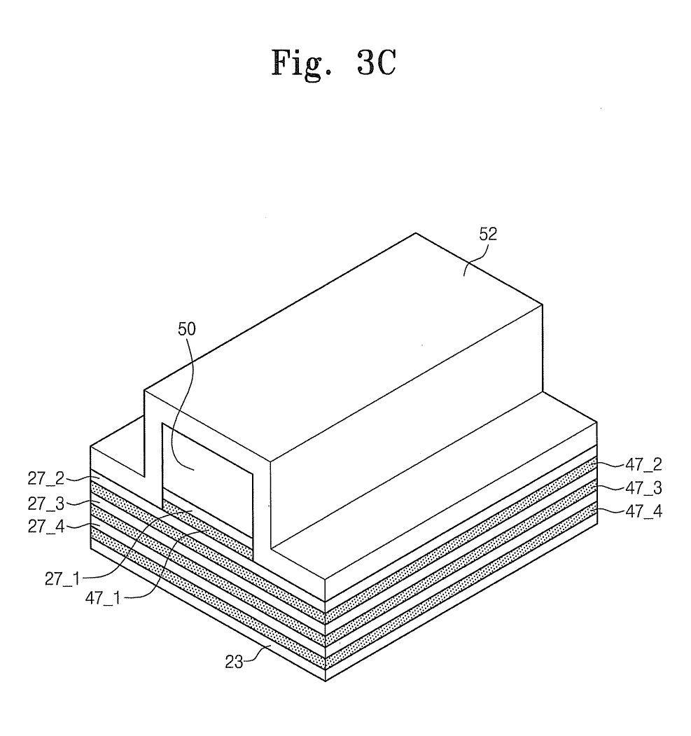

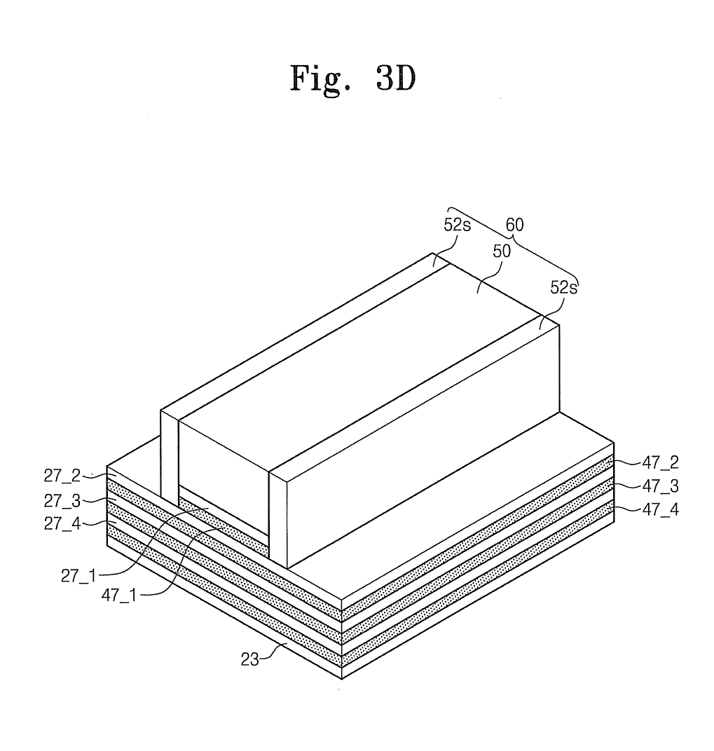

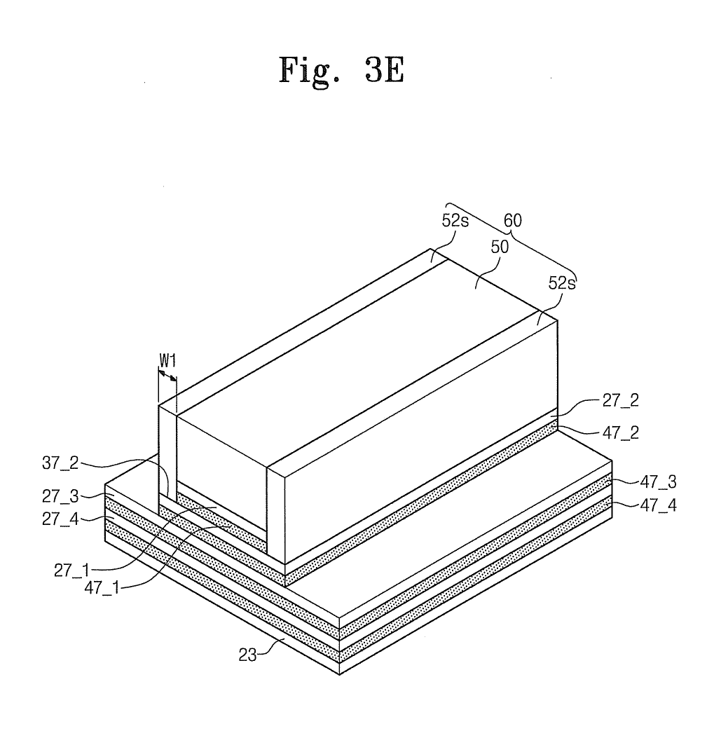

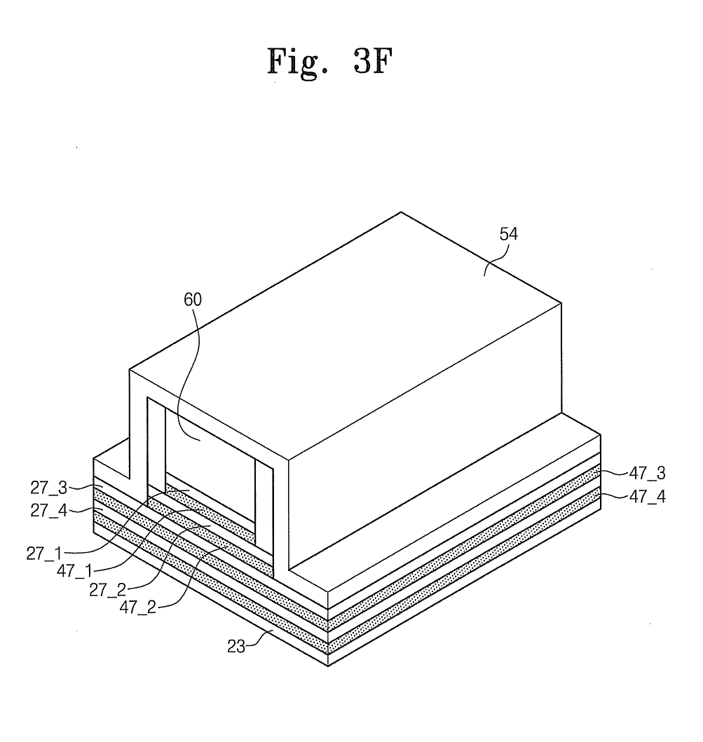

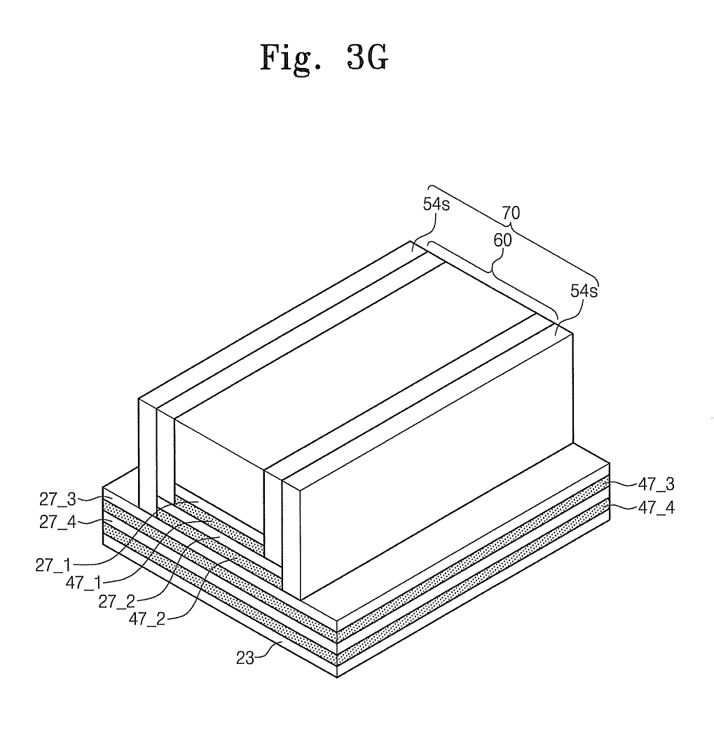

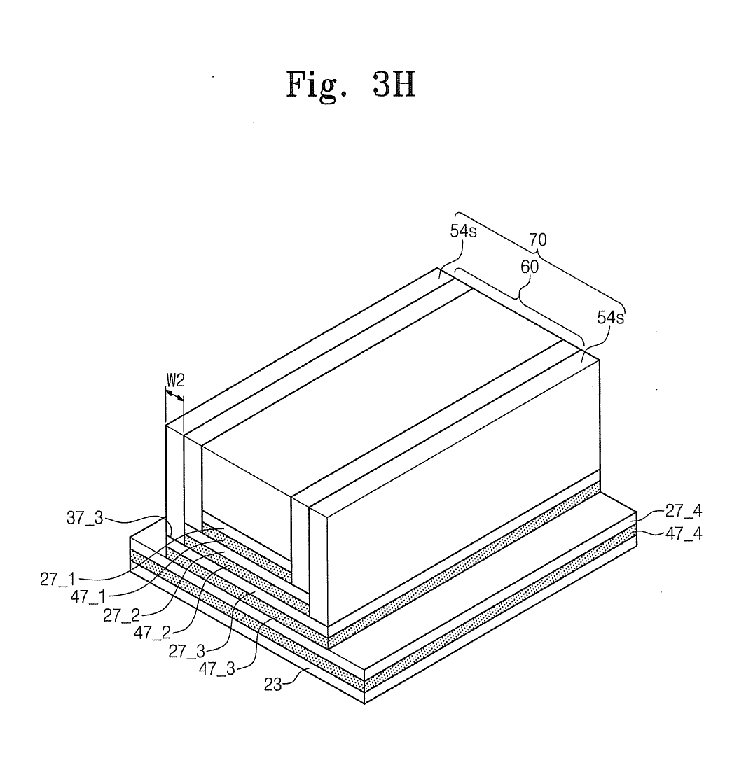

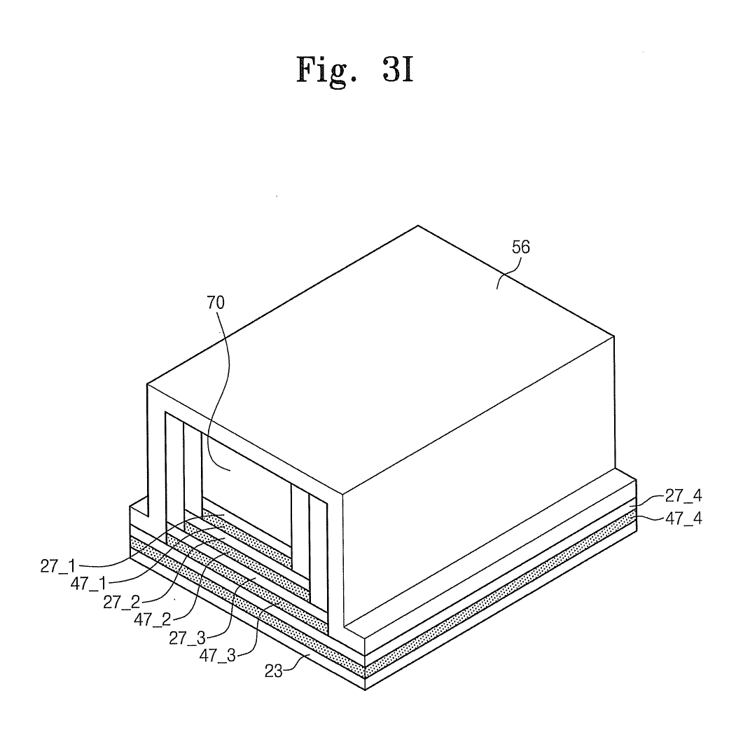

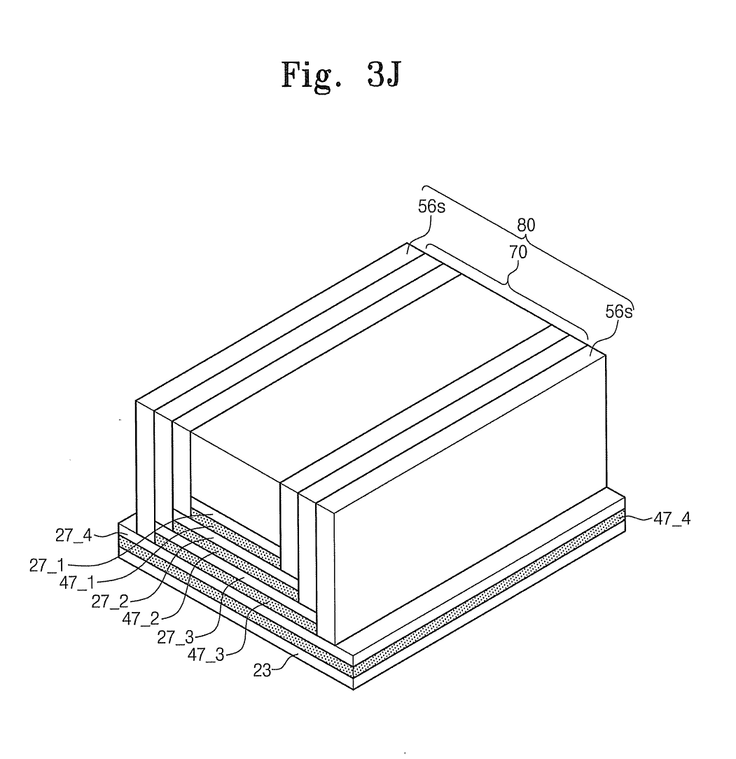

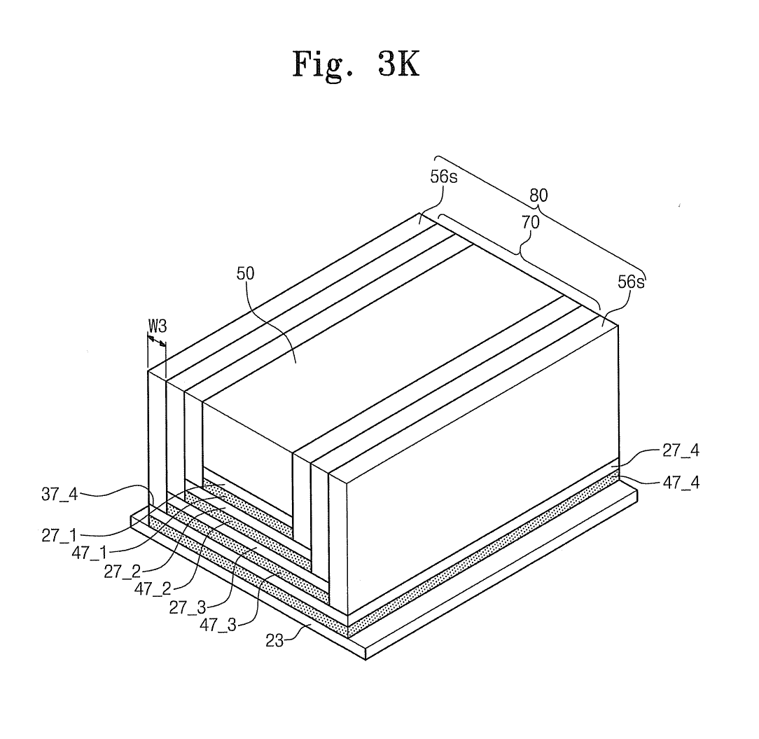

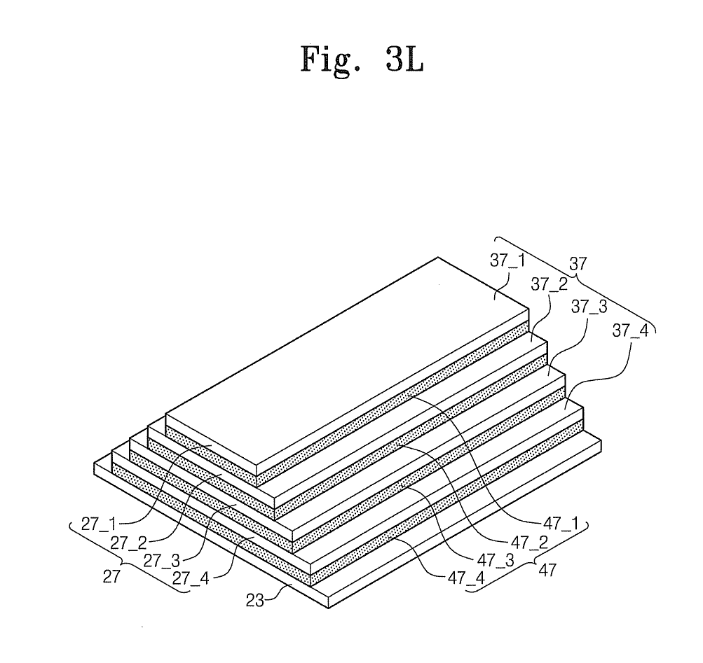

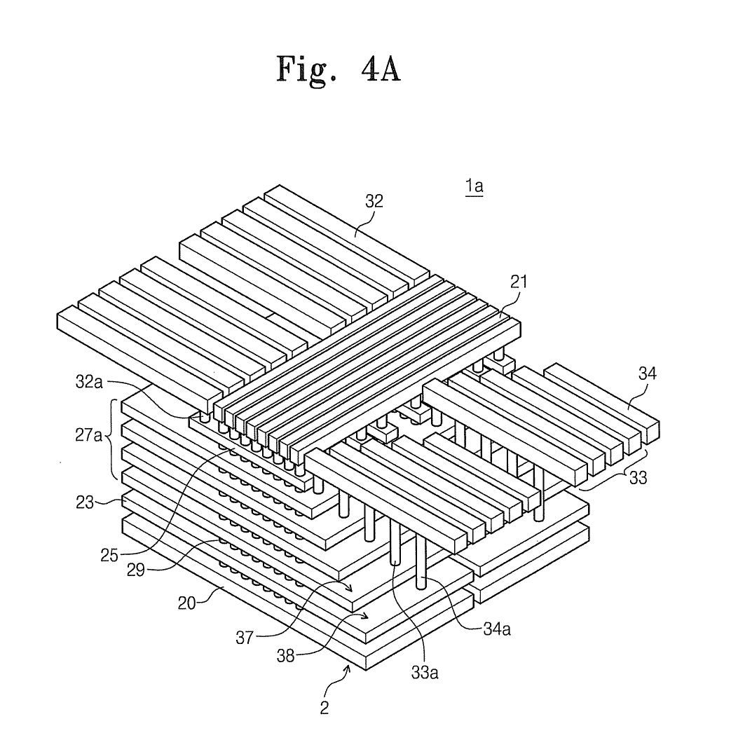

FIGS. 3A-3L are perspective views illustrating methods of manufacturing stair-type structures according to example embodiments of the inventive concepts. Referring to FIG. 3A, a plurality of insulating layers 47 and a plurality of control gates 27 may be formed alternately on the lower selection gate 23. The control gates 27 may be formed into plate shape. The control gates 27 may be assigned reference numbers in drawings as 27_1-27_4. The insulating layers 47 may be assigned reference numbers in drawings as 47_1-47_4. A first mask 50 may be formed on a first control gate 27_1. The first mask 50 may be formed of, for example, a photoresist using a photolithography process. The first mask 50 may be formed to cross over the center region of the first control gate 27_1. Although the control gates 27 and the insulating layers 47 are illustrated such that there are 4 of each, example embodiments are not so limited. The number of layers may be determined according to, for example, a number of memory cells of a memory cell string.

Referring to FIG. 3B, the first control gate 27_1 may be patterned by a first pad etch using the first mask 50 as an etch mask. The first insulating layer 47_1 may be patterned in the first pad etch such that a second control gate 27_2 is exposed. The first pad etch may be a dry etch process. Top surfaces of both edge regions of the first control gate 27_1 may be first word line pads 37_1.

Referring to FIG. 3C, a first pre-spacer layer 52 may be formed on the second control gate 27_2 to cover the first mask 50. The first pre-spacer layer 52 may be formed by depositing, for example, a polymer layer. For example, the first pre-spacer layer 52 may be formed in a deposition process using plasma in which a gas containing C-H-F, N₂ and Ar are included. The first pre-spacer layer 52 may be a polymer, for example, a carbon polymer containing carbon and hydrogen.

Referring to FIG. 3D, a portion of the first pre-spacer layer 52 may be removed by a spacer etch to form a first spacer 52s on each sidewall of the first mask 50. The first mask 50 and the first spacer 52s may be a second mask 60. The spacer etch may be performed using, for example, plasma. The plasma may contain the same gas used for forming the first pre-spacer layer 52. For example, the first pre-spacer layer 52 may be etched in a dry etch process using plasma in which a gas containing C-H-F, N₂ and Ar are included.

The polymer deposition process of FIG. 3C and the polymer etch process of FIG. 3D may be performed using the same plasma. The polymer deposition process and the polymer etch process may be performed in-situ. The deposition of the gates 23 and 27 and the pad etch may be performed in-situ with the polymer deposition and etch processes. The process condition may be different in the polymer deposition process and the polymer etch process while the processes may be performed using the same plasma. Because at least carbon or carbon and hydrogen in the gas containing C-H-F may affect the polymer deposition and the fluorine may affect the polymer etch, the content of carbon and hydrogen may be raised in the polymer deposition process and the content of fluorine may be raised in the polymer deposition process. For example, methyl fluoride (CH₃F) may be provided in the polymer deposition process of FIG. 3C, and trifluoromethane (CHF₃), carbon tetrafluoride (CF₄) or a mixture thereof may be provided in the polymer etch process of FIG. 3D. In the polymer etch process, oxygen (O₂) may be further provided. Power may be applied to control gate 27 to enhance directivity of an etchant.

Referring to FIG. 3E, the second control gate 27_2 and the second insulating layer 47_2 may be etched by a second pad etch using the second mask 60 as an etch mask. Top surfaces of both edges of the second control gate 27_2 may form a second word line pad 372. A width of the second word line pad 37_2 may depend on a first width W1 of the first spacer 52s. The width of the second word line pad 37_2 may be determined according to the thickness of the first pre-spacer layer 52 (e.g., in addition to the width of the first mask 50).

Referring to FIGS. 3F-3H, using the same or similar methods as described with reference to FIGS. 3C-3E, a second pre-spacer layer 54 may be formed by, for example, a polymer deposition process using plasma to cover the second mask 60. A portion of the second pre-spacer layer 54 may be removed by a spacer etch process using the plasma to form a spacer on each sidewall of the second mask 60. A third mask 70 may be formed. Portions of the third control gate 27_3 and the third insulating layer 473 may be removed by a third pad etch process using the third mask 70 as an etch mask to define the top surface of both edges of the third control gate 27_3 as a third word line pad 373. The width of the third word line pad 37_3 may depend on the second width W2 of the second spacer 54s (e.g., the width of the second mask 60 and the second width W2).

Referring to FIGS. 3I-3K, using the same or similar methods as described with reference to FIGS. 3C-3E, a third pre-spacer layer 56 may be formed by, for example, a polymer deposition process using plasma to cover the third mask 70. A portion of the third pre-spacer layer 56 may be removed by a spacer etch process using the plasma to form a spacer on each sidewall of the third mask 70. A fourth mask 80 may be formed. Portions of the fourth control gate 27_4 and the fourth insulating layer 47_4 may be removed by a fourth pad etch process using the fourth mask 80 as an etch mask to define the top surface of both edges of the fourth control gate 27_4 as a fourth word line pad 37_4.

The width of the fourth word line pad 37_4 may depend on the third width W3 of the third spacer 56s (e.g., the width of the fourth mask 80 and the width W3). As shown in FIG. 3K, the top surface of both edges of the lower selection gate 23 may be exposed by the fourth pad etch. The exposed surface of the lower selection gate 23 may be a lower selection line pad. Referring to FIG. 3L, the fourth mask 80 may be removed by an ash process. As the result of the above processes, a plurality of the control gates 27 may be vertically stacked and formed into stair type structure with plurality of the word line pads 37. The insulating layers 47 may be also formed into stair type structure.

According to example embodiments, spacers may be formed on lateral sidewalls of a mask. The mask may not expand or shrink. The widths W1-W3 of the first through third spacer 52s, 54s and 56s may be uniform in dimensions such that the widths of a plurality of the word line pad 37 may be formed uniformly. In the patterning method of an example embodiment, the stair type structure may be obtained using only one photo lithography process in which the first mask 50 is formed.

The spacer material is not limited to a polymer but may be selected from materials with etch selectivity to the insulating layer 47, for example, a silicon oxide layer, a silicon nitride layer, a silicon carbide layer and/or a combination thereof. The material of the spacer layers 52-56 may be selected from, for example, a metal, a metal oxide layer and/or a metal nitride layer. The method of forming the stair type structure is not limited to use for forming the control gate. The method can be widely used to form a stacked stair type structure. For example, a stacked stair type structure of conductive layers and/or electrodes.

Referring to FIG. 2E, a slit 19 may be formed to divide each of the gates 23 and 27. The gates 23 and 27 may be separated into two regions such that two devices are formed on the semiconductor substrate 20. A plurality of upper selection gates 25 may be formed on the uppermost control gate 27. The upper selection gate 25 may be formed into plate type and/or line type. The upper selection gate 25 may be formed of the same or similar material to the control gate 27 and/or the lower selection gate 23. For example, the upper selection gate 25 may be formed of poly crystalline silicon. Each selection gate 25 may be connected with a plurality of the second pillars 29b.

Referring to FIG. 2F, a plurality of third pillars 29c may be formed to connect with the plurality of the second pillars 29b through the upper selection gate 25. The third pillars 29c may be formed by, for example, a deposition and/or an epitaxial process. For example, a hole may be formed using a dry etch to expose the second pillars 29b through the upper selection gate 25, and the hole may be filled with a conductive material to form the third pillars 29c. The third pillars 29c may be formed of the same or similar material to the first pillars 29a and/or the second pillars 29b. For example, the third pillars 29c may be formed of amorphous, monocrystalline and/or polycrystalline silicon.

A third gate insulating layer (not shown) may be formed between the third pillar 29c and the upper selection gate 25, thereby forming the same or similar structure as shown in FIG. 1C. The third gate insulating layer may be formed by depositing a silicon oxide layer and/or a silicon nitride layer. The first through third pillars 29a-29c may be connected in series to compose an active pillar 29. The first through the third pillars 29a-29c may be of the same conductivity type as the semiconductor substrate 20, for example P-type. The semiconductor substrate 20 and the active pillar 29 may be of equipotential.

Referring to FIG. 2G, a plurality of bit lines 21 may be formed to be connected with the active pillars 29. Each bit line 21 may be connected with a plurality of the active pillars 29 arranged along the bit lines 21. The bit lines 21 may cross over the upper selection gates 23, for example, the bit lines 21 may be perpendicular to the upper selection gates 23. A cell string 22 may be defined by a bit line 21 and an upper selection gate 25. A drain may be formed at a portion of the active pillars 29 which is adjacent to the bit lines 21. Contact plugs may be further formed between the active pillars 29 and the bit lines 21.

Referring to FIG. 2H, a plurality of first contact plugs 32a may be formed on the upper selection gates 25. A plurality of first lines 32 may be formed to connect with the first contact plugs 32a. The first lines 32 may electrically connect the upper selection gates 25 to an upper selection line drive circuit. A plurality of second contact plugs 33a may be formed on the word line pads 37. A plurality of second lines 33 may be formed to connect with the second contact plugs 33a. The second lines 33 may connect the control gates 27 to a word line drive circuit. A third contact plug 34a may be formed on the lower selection line pad 38 of the lower selection gate 23 and a third line 34 may be formed to connect with the third contact plug 34a. The third line 34 may connect the lower selection gate 23 to a lower selection line drive circuit. The first through third contact plugs 32a, 33a and 34a may be formed simultaneously by depositing a metal layer. The first through third lines 32, 33 and 34 may also be formed simultaneously by depositing a metal layer. As a result of the above methods, a non-volatile memory device may be formed to include control gates 27 with a stair type structure.

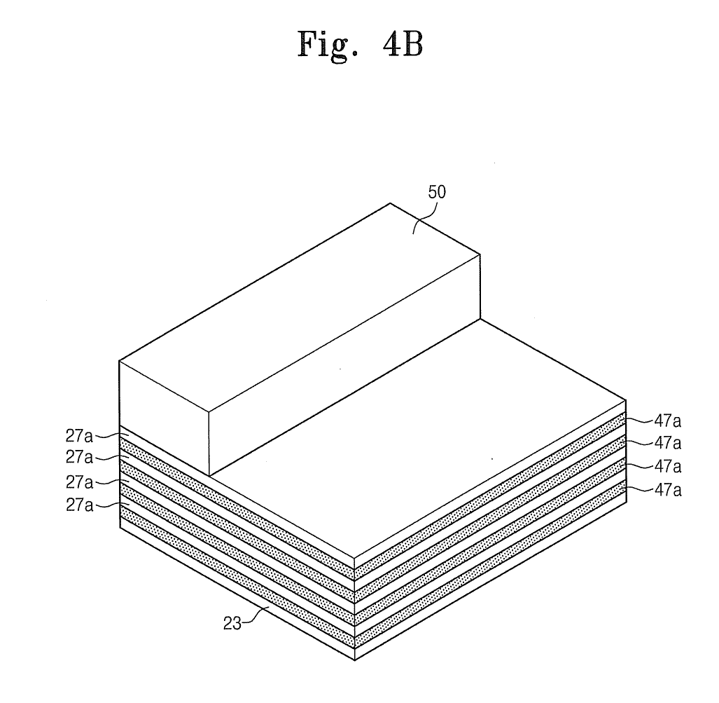

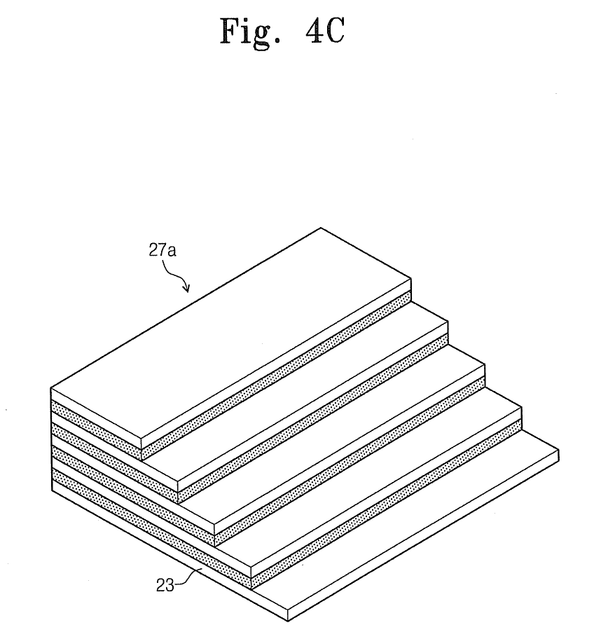

FIG. 4A is a perspective view illustrating nonvolatile memory devices according to another example embodiment of the inventive concepts. FIGS. 4B and 4C are perspective views illustrating methods for forming a stair-type structure of a nonvolatile memory device according to example embodiments of the inventive concepts. Referring to FIG. 4A, a nonvolatile memory device 1a according to another example embodiment may include a plurality of control gates 27a stacked on a stair type structure at one side. A plurality of contact plugs 33a may be formed on the stair type structured side. The nonvolatile memory device 1a may be a similar structure to the nonvolatile memory device of FIG. 1A except for the stair type structure.

Referring to FIGS. 4B and 4C, control gates 27a may be formed to be a stair type structure on one side by using the same or a similar manufacturing method as described with referenced to FIGS. 3A-3L. For example, as shown in FIG. 4B, a plurality of control gates 27a and a plurality of insulating layers 47a may be alternately formed into plate shape on a lower selection gate 23. A first mask 50 may be formed on a side portion of the top surface of the uppermost control gate 27a. A polymer deposition and a polymer etch, for example, may be performed to form a spacer on one sidewall of the first mask 50. A pad etch may be performed. The forming of the spacer and the pad etch may be repeatedly performed to form a stair type structure of the control gate 27a as shown in FIG. 4C.

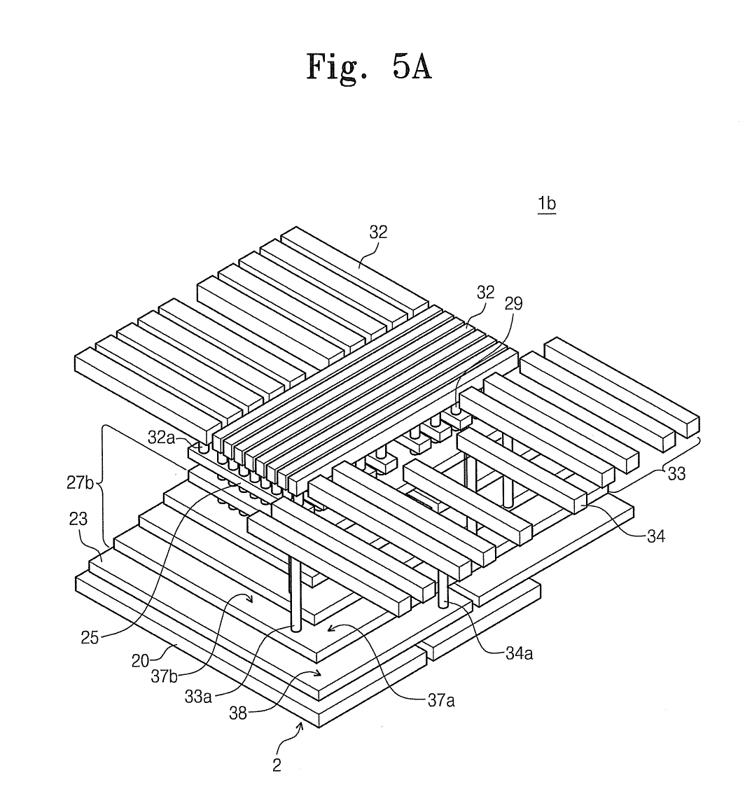

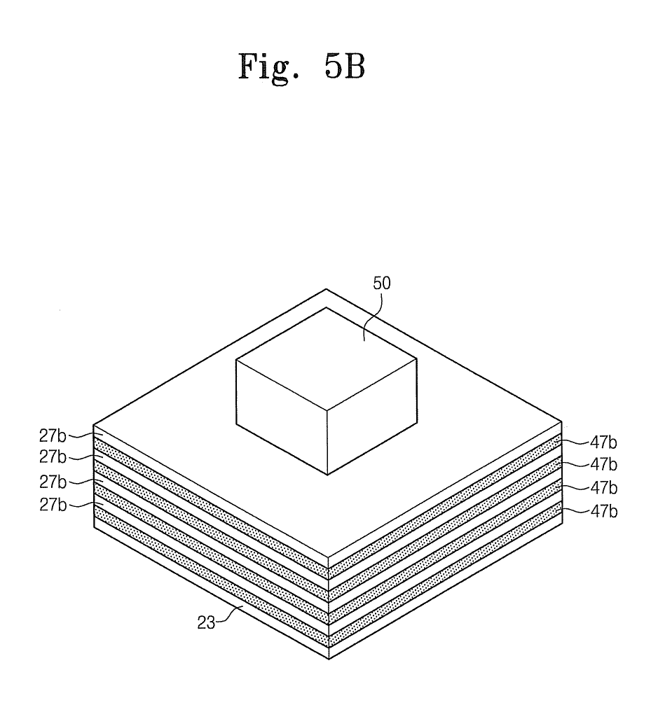

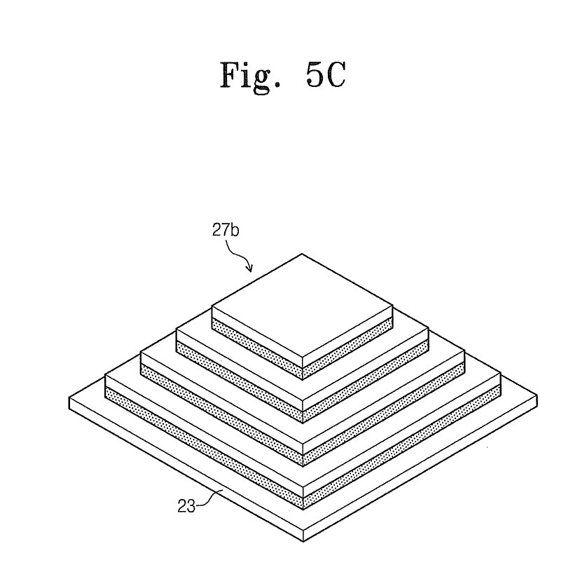

FIG. 5A is a perspective view illustrating nonvolatile memory devices according to example embodiments of the inventive concepts. FIGS. 5B and 5C are perspective views illustrating methods of manufacturing a stair-type structure of nonvolatile memory devices according to example embodiments of the inventive concepts. Referring to FIG. 5A, a nonvolatile memory device 1b according to another example embodiment of the inventive concepts may include a plurality of control gates 27b which are stacked in a pyramid shape with a stair type structure on four sides. Second contacts 33a are arranged on two adjacent word line pads 37a and 37b. There may be a difficulty to form all of the second lines 33 at one side of the control gates 27b. Some of the second lines 33 may be formed on another word line pad.

Referring to FIGS. 5B and 5C, methods that are the same or similar to those described with reference to FIGS. 3A-3L may be performed to form control gates 27b which are stacked in pyramid shape having a stair type structure on, for example, 4 sides. For example, referring to FIG. 5B, plate type control gates 27b and insulating layers 47b may be alternately formed on the lower selection gate 23. A first mask 50 may be formed on a top surface of the uppermost control gate 27b. A portion of top surface of the uppermost control gate 27b may be exposed around the first mask 50. Pad etches may be sequentially performed in correspondence a sequential increase of the width of the first mask 50 to form pyramid shaped control gates 27b.

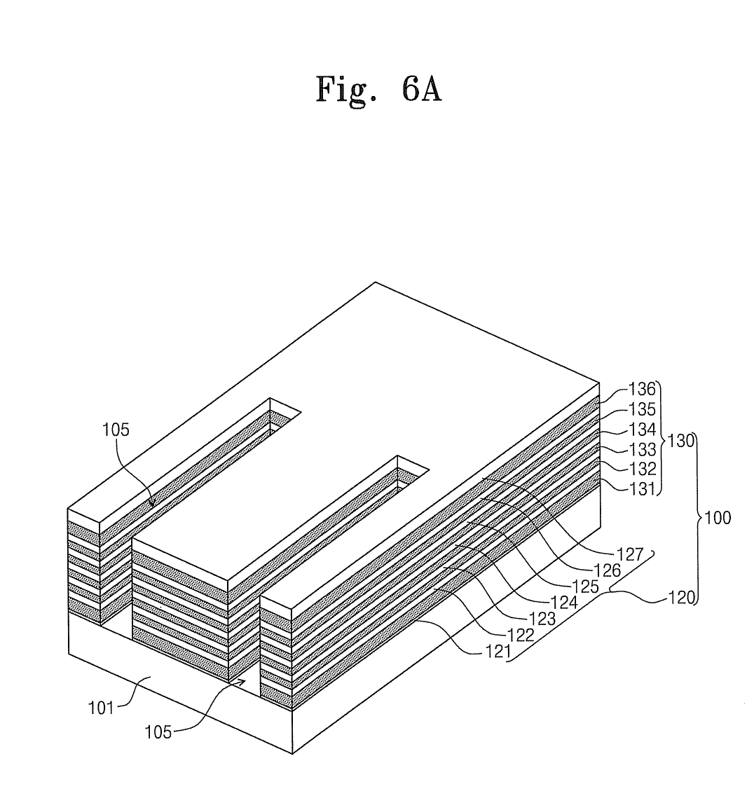

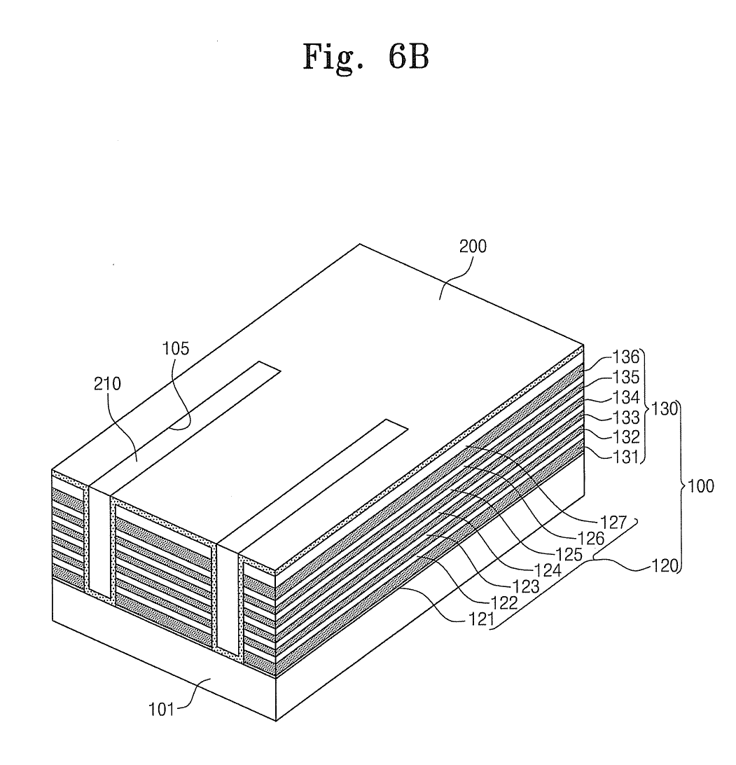

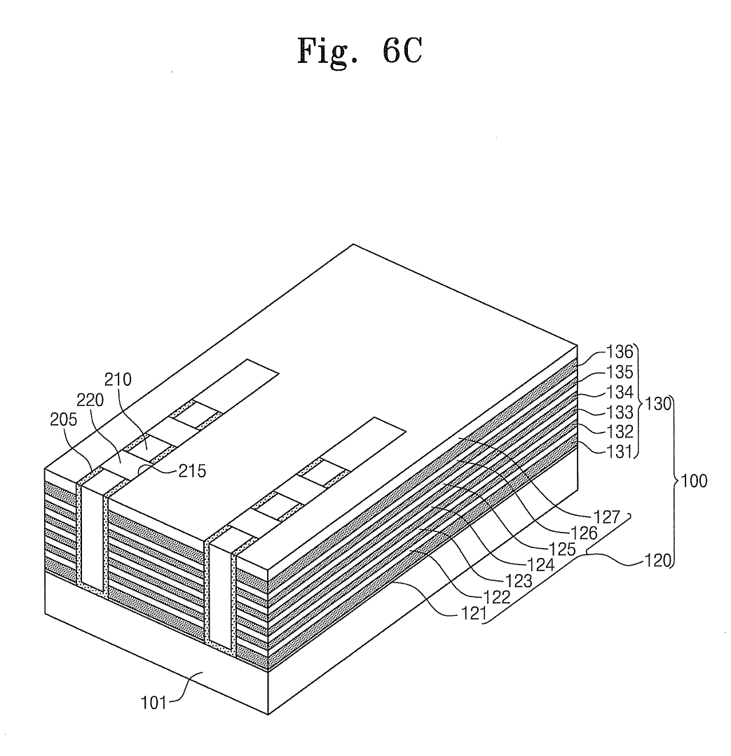

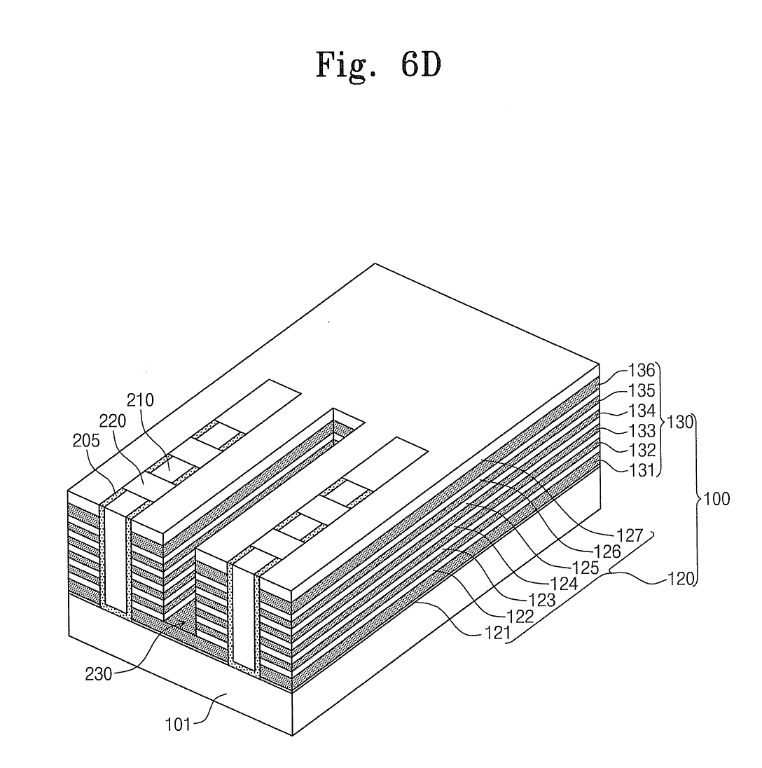

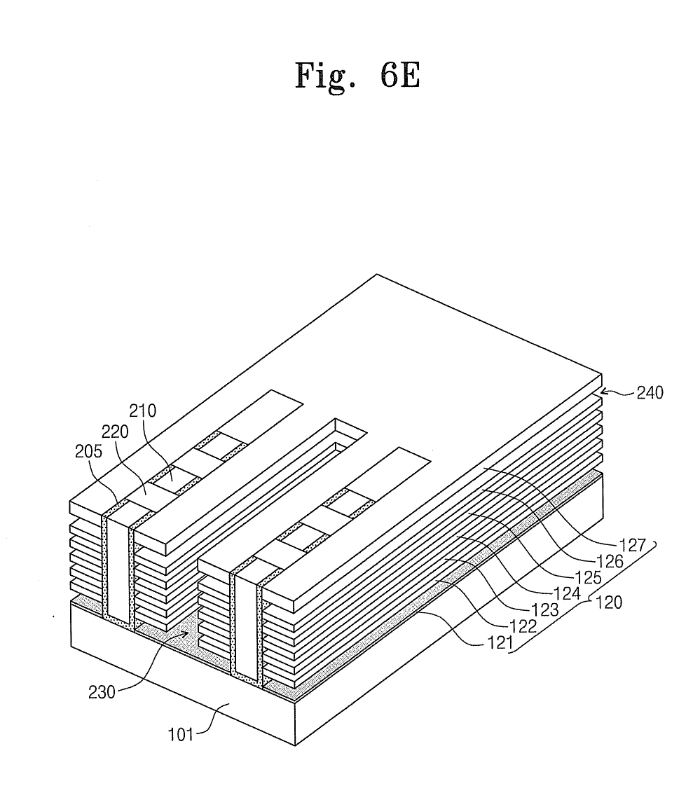

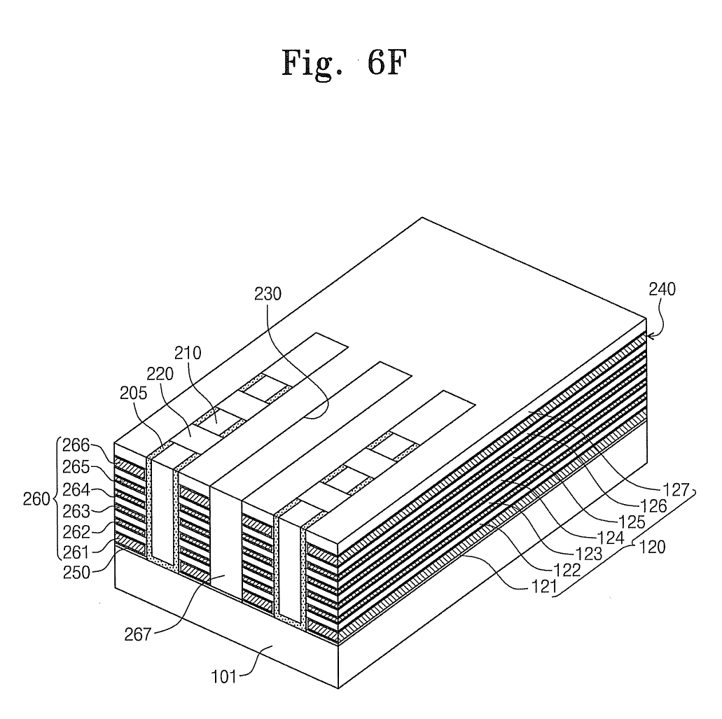

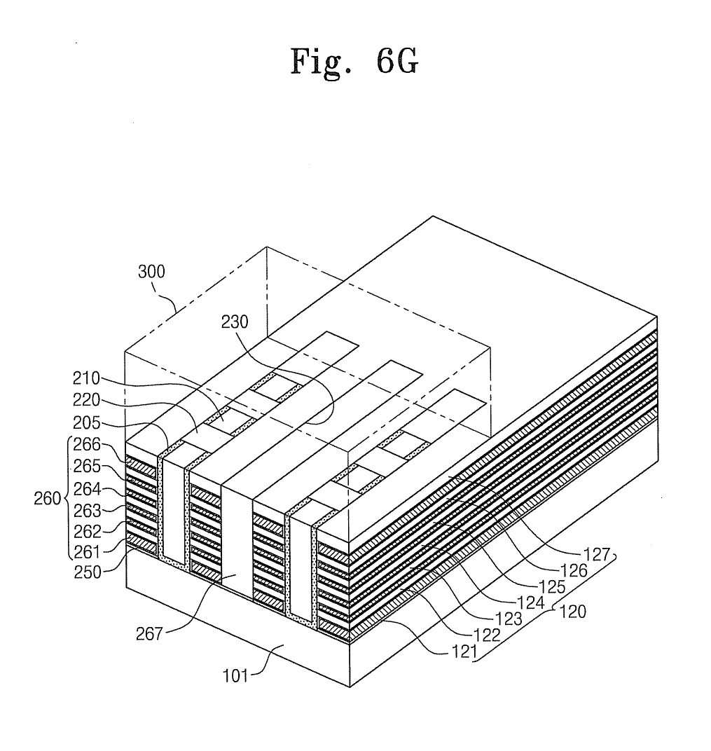

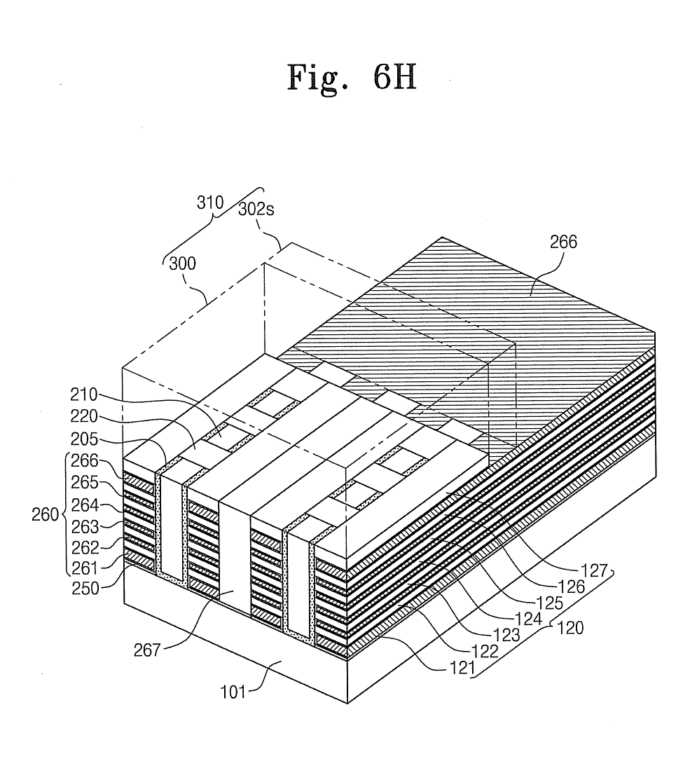

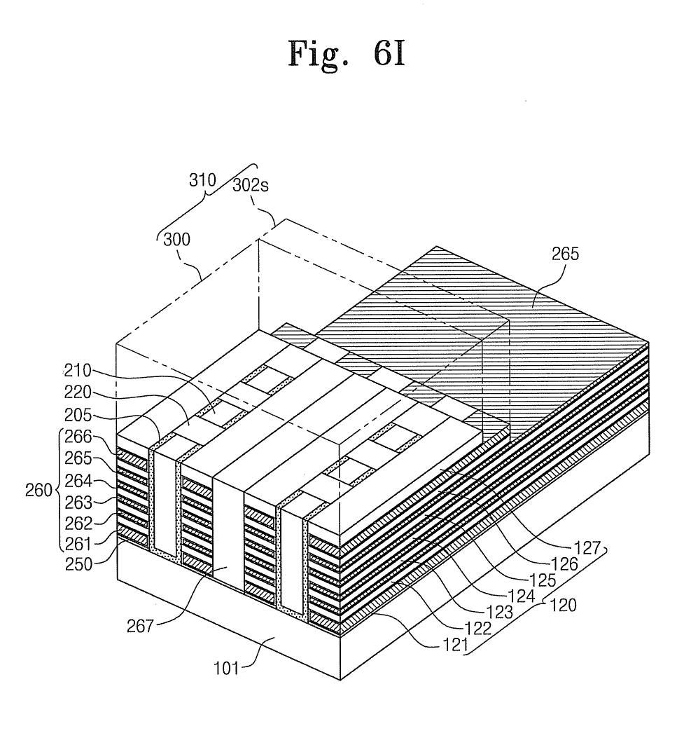

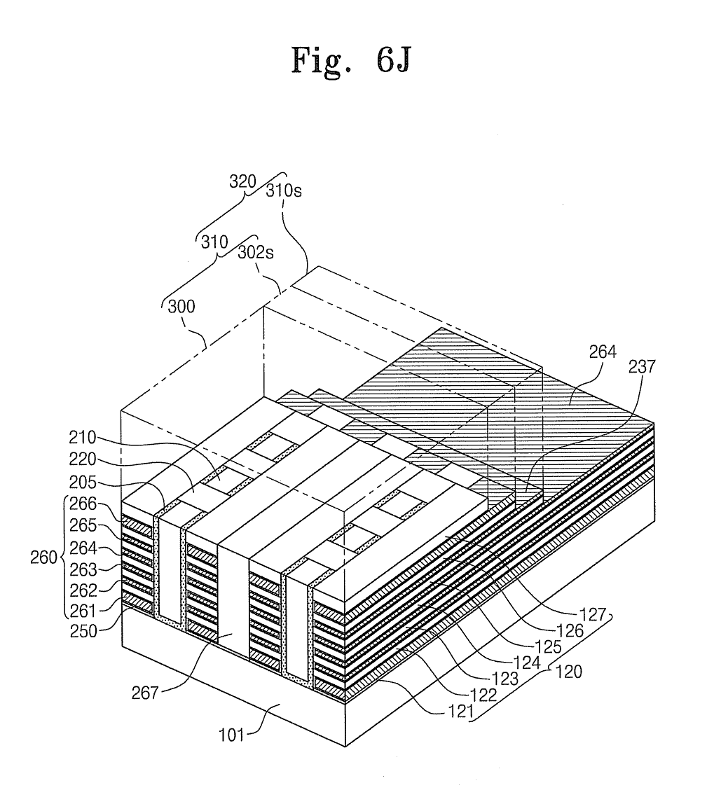

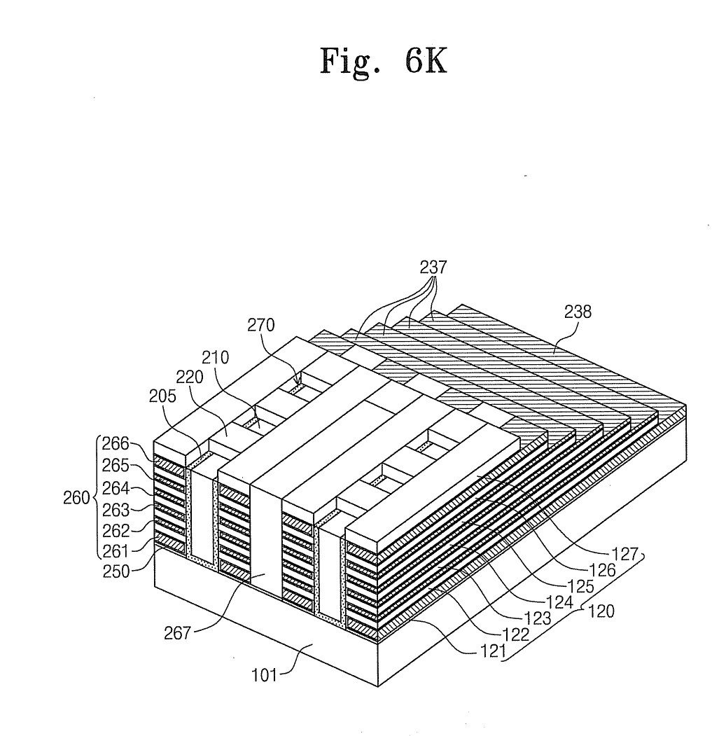

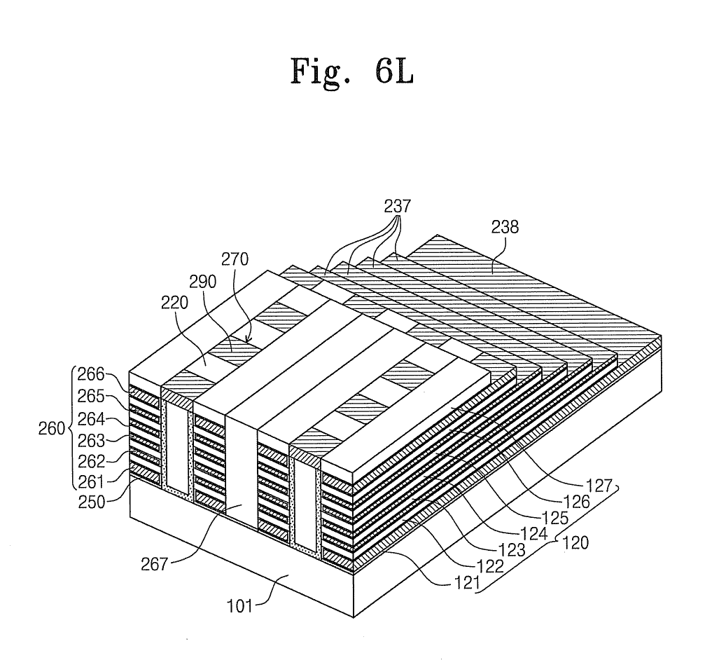

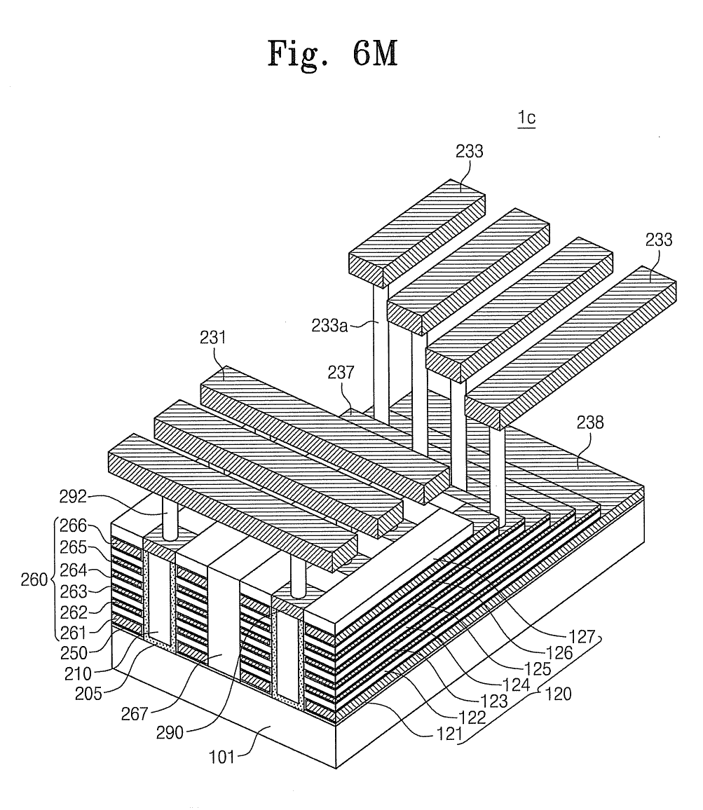

FIGS. 6A-6M are perspective views illustrating methods of manufacturing nonvolatile memory devices according to example embodiments of the inventive concepts. Referring to FIG. 6A, an insulating layer 120 may include insulating layers 121-127 and a sacrificial layer 130 may include sacrificial layers 131-136. The insulating layers 121-127 may be alternately formed with the sacrificial layers 131-136 on a semiconductor substrate 101 to form a thin layer structure 100. The insulating layer 120 and the sacrificial layer 130 may have etch selectivity to each other. For example, the insulating layer 120 may be formed of a silicon oxide layer and/or a silicon nitride layer. The sacrificial layer 130 may be formed of a different material than the insulating layer 120, for example, a silicon layer, a silicon oxide layer, a silicon nitride layer, and/or a silicon carbide layer. A first opening 105 may be formed to expose the semiconductor substrate 101 through the thin layer structure 100. The first opening 105 may be formed into a tetragon, circle and/or ellipsoid shape. The insulating layer 121-127 will be related to sacrificial layers 131-136 according to a stacking order.

Referring to FIG. 6B, a semiconductor layer 200 may be formed to cover the thin layers structure 100. The semiconductor layer 200 may be formed to be substantially conformal to the inner wall of the first opening 105. A first buried pattern 210 may be formed to fill the first opening 105. The semiconductor layer 200 may be formed of, for example, monocrystalline and/or polycrystalline silicon by, for example, a deposition and/or an epitaxial process. The first buried pattern 210 may be formed, for example, of a silicon oxide layer by a deposition process to fill the first opening 105. The first buried pattern 210 may be formed using spin on glass (SOG) technology.

Referring to FIG. 6C, the semiconductor layer 200 may be patterned to form a semiconductor patterns 205 which may be confined in the first opening 105. A second opening 215 between the semiconductor patterns 205 may be filled with an insulating layer to form a second buried pattern 220. The semiconductor substrate 101 may be exposed in the second opening 215. The semiconductor patterns 205 may be formed by patterning the first buried pattern 210 using a mask crossing a longitudinal axis of the first opening 105 to form the second opening 215 in which the semiconductor layer 200 formed on the inner wall of the first opening 105 is exposed, and by etching the exposed semiconductor layer 200 in the second opening 215. The second buried pattern 220 may be formed by forming an insulating layer to fill the second opening 215 and by planarizing the insulating layer and the semiconductor layer 200 until the top surface of the thin layer structure 100 is exposed. The semiconductor pattern 205 may be used as an active pillar (e.g., a structure the same or similar to that illustrated in FIG. 1D).

Referring to FIG. 6D, a trench 230 may be formed to penetrate entirely or partially through thin layers 120 and 130 of the thin layer structure 100. The trench 230 may be formed separated from the semiconductor pattern 205 to expose sidewalls of the sacrificial layer 130 and the insulating layer 120. The trench 230 may be formed into, for example, a line and/or rectangular shape. The trench 230 may be formed to a depth sufficient to expose at least the first sacrificial layer 131 or the semiconductor substrate 101.

Referring to FIG. 6E, the sacrificial layer 130 exposed in the trench 230 may be selectively removed to form recess regions 240 between the insulating layers 121-127. The recess regions 240 may be gap regions which extend from the trench 230 to the spaces between the insulating layers 121-127. The semiconductor pattern 205 may be exposed by the recess regions 240. The forming of the recess regions 240 may include an isotropic etch of the sacrificial layer 130 using an etch recipe in which the sacrificial layer 130 is selectively etched with respect to the insulating layer 120. For example, if the sacrificial layer 130 is silicon nitride and the insulating layer 120 is silicon oxide, the etch may be performed using an etchant containing phosphoric acid.

Referring to FIG. 6F, an information storage layer 250 and gates 260 may be formed in the recess regions 240. The information storage layer 250 may include a charge storage layer between a tunnel insulating layer and a blocking insulating layer. The charge storage layer may include a silicon nitride layer and/or a floating gate. The gates 260 may be formed into a plate shape by, for example, depositing polycrystalline silicon and/or metal. The polycrystalline silicon and/or metal may also fill the trench 230 in the deposition process for forming the gates 260. In this case, the polycrystalline silicon, or the polycrystalline silicon and information storage layer 250 filling the trench 230, may be removed using an etch process followed by filling the trench 230 with an insulating layer to form a third buried pattern 267. The third buried pattern 267 may be formed of a silicon oxide layer, a silicon nitride layer, a silicon oxynitride layer, or a combination thereof. The first gate 261 of the gates 260 may be a lower selection gate as a ground selection line, the sixth gate 266 may be an upper selection gate as a string selection line and the second through the fifth gates 262-265 may be control gates as word lines.

Referring to FIG. 6G, the same or similar methods as described with reference to FIGS. 3A-3L may be used to form a stair type structure of the gates 260. For example, a first mask 300 may be formed. The first mask 300 may be a photoresist which is formed on the seventh insulating layer 127 to partially cover the second buried pattern 220 and the third buried pattern 230. Referring to FIG. 6H, portions of the seventh insulating layer 127 and the second and the third buried pattern 220 and 267 may be removed by, for example, a dry etch using the first mask 300 as an etch mask. The dry etch may be performed to expose the sixth gate 266. A portion of the information storage layer 250 on the sixth gate 266 may be also removed in the dry etch. A first spacer 302s may be formed on a sidewall of the first mask 300. The first spacer 302s may be formed to cover the second and third buried patterns 220 and 267 which are not covered by the first mask 300. The first spacer 302s may be formed by, for example, forming a pre-spacer layer to cover the first mask 300 and the sixth gate 266 followed by spacer etching the pre-spacer layer. The first spacer 302s may be formed of, for example, a photoresist, an insulating layer and/or a polymer. According to example embodiments, a polymer deposition using plasma containing CH₃F may be performed to form a pre-spacer layer, and a polymer etch may be performed in-situ with the polymer deposition using plasma containing CHF₃ and/or CF₄. The first spacer 302s may be formed. The first mask 300 and the first spacer 302s may compose a second mask 310.

Referring to FIG. 6I, a portion of the sixth gate 266 may be removed by, for example, a dry etch using the second mask 310 as an etch mask. The sixth insulating layer 126 and the information storage layer 250 on and under the sixth insulating layer 126 may be etched simultaneously with the sixth gate 266. The fifth gate 265 may be exposed. The sixth gate 266 may be an upper selection gate and formed into a line shape separated by the second and third buried patterns 220 and 267. According to example embodiments, the methods of forming the upper selection gate 266 into line shape may be omitted.

Referring to FIG. 6J, a polymer layer may be deposited and etched to fowl a second spacer 310s on the sidewall of the second mask 310. The second mask 310 and the second spacer 310s may be a third mask 320. A portion of the fifth gate 265 may be removed by dry etching using the third mask 320 as an etch mask to define a word line pad 237. The fifth insulating layer 125 and the information storage layer 250 on and under the fifth insulating layer 125 may be etched simultaneously with the fifth gate 265. The fourth gate 264 may be exposed.

Referring to FIG. 6K, the mask width is sequentially increased by deposition and etching of the polymer. Dry etching may be performed using the sequentially increased mask to form upper selection gates 266 separated from each other, control gates 262-265 and a lower selection gate 261, which are stacked into stair type structure. Word line pads 237 may be on the control gates 262-265, and a lower selection line pad 238 may be on the lower selection gate 261. The semiconductor pattern 205 and the first buried pattern 220 may be selectively recessed to form a groove 270.

Referring to FIG. 6L, the groove 270 may be filled with polysilicon, metal and/or another conductive material to form a bit line pad 290 connected to the semiconductor pattern 205. According to example embodiments, a bit line pad 290 may be formed on the first buried pattern 210 without forming the groove 270. Referring to FIG. 6M, a bit line plug 292 may be formed to be connected to the bit line pad 290 and a bit line 231 may be formed to be connected to the bit line plug 292. Contact plug 233a may be formed to be connected to the word line pads 237 and a plurality of metal lines 233 connected to the contact plugs 233a may be formed to connect the control gates 262-265 with a word line drive circuit. Nonvolatile memory device 1c may be formed by the above methods.

Not shown in drawings, a plurality of metal lines may be formed to connect a plurality of the upper selection gates 265 with an upper selection line drive circuit and a plurality of metal lines for connecting the lower selection gate 261 with a lower selection line drive circuit. The gates 261-266 may be patterned into a stair type structure on two sides as shown in FIGS. 3A-3L, patterned into stair type structure on one side as shown if FIGS. 4B and 4C, and/or patterned into pyramid type structure as shown in FIGS. 5B and 5C.

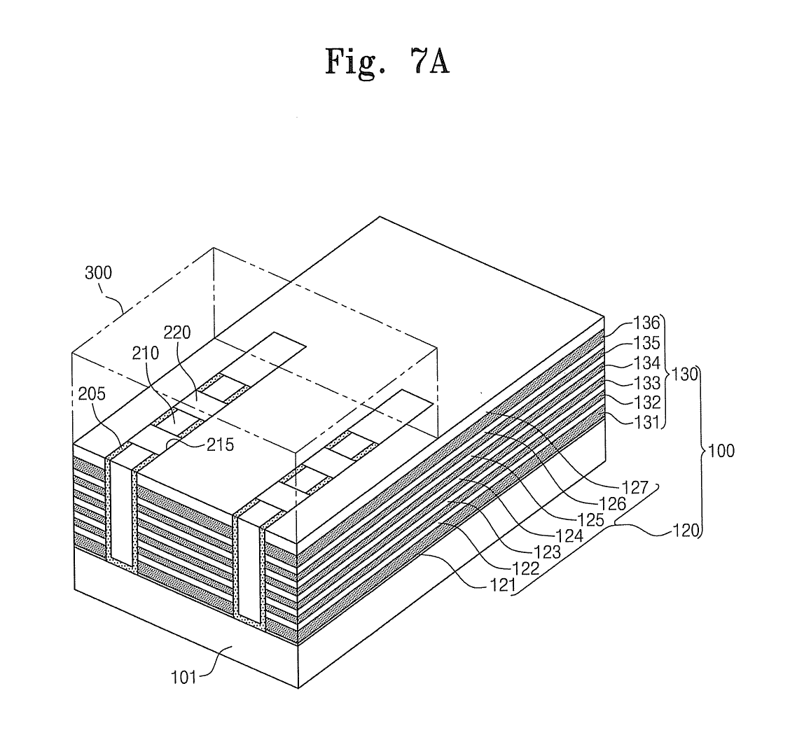

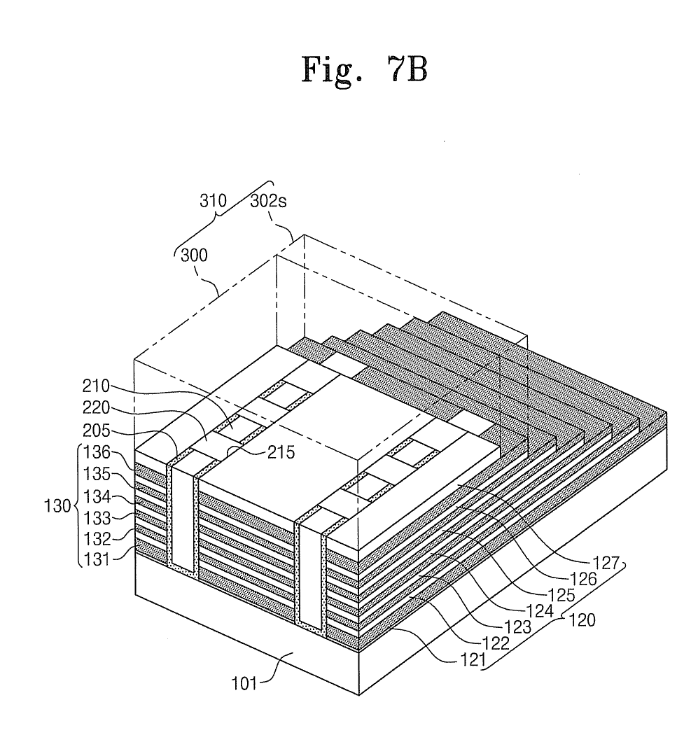

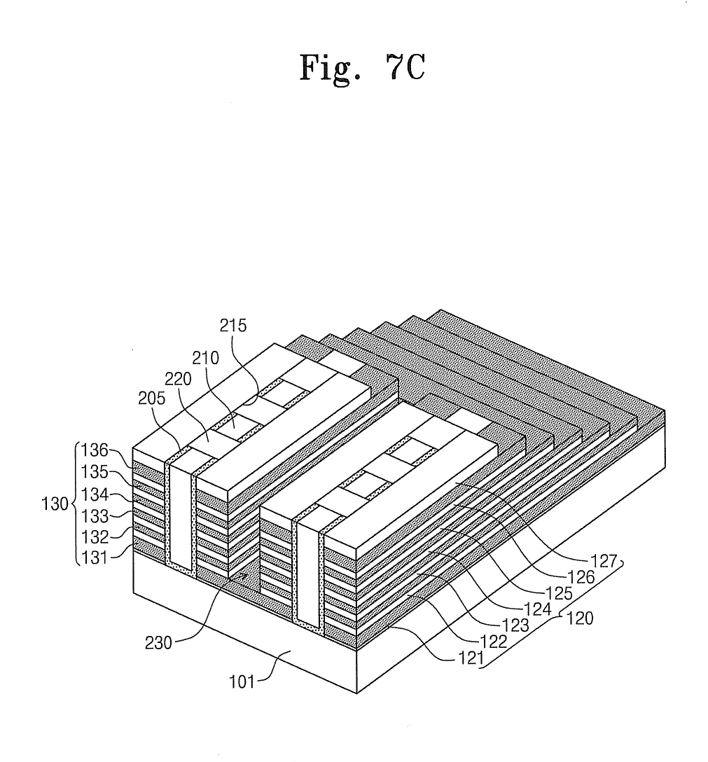

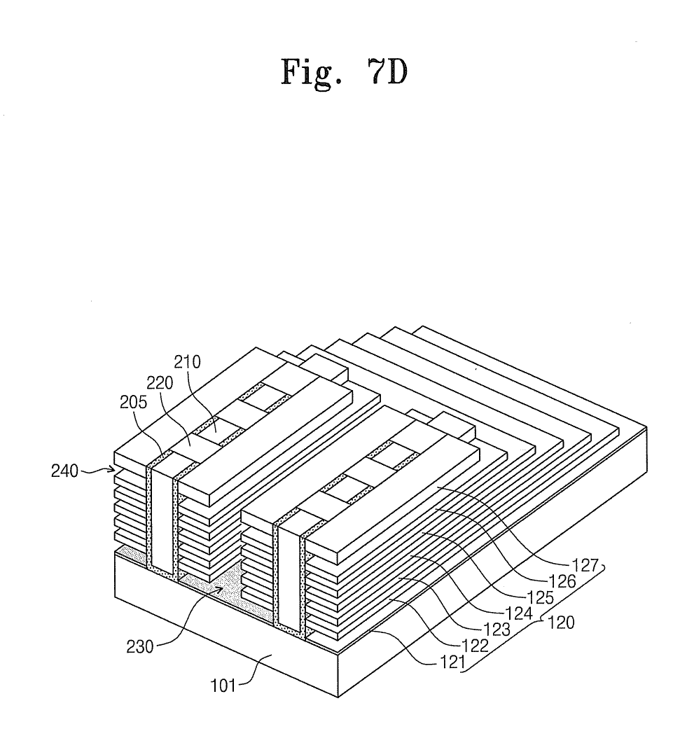

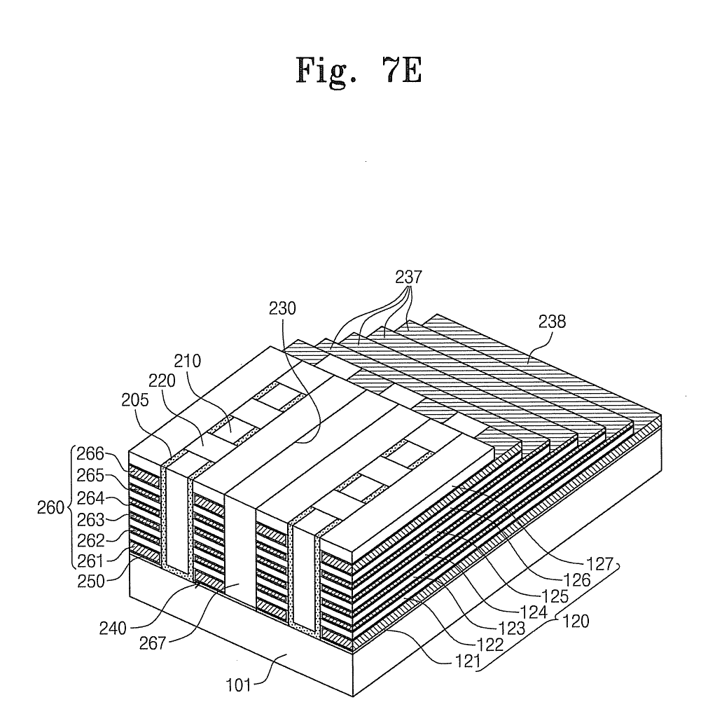

FIGS. 7A-7E are perspective views illustrating nonvolatile memory devices according to example embodiments of the inventive concepts. Referring to FIG. 7A, insulating layers 121-127 and sacrificial layers 131-136 may be formed on a semiconductor substrate 101 to form a thin layer structure 100. A first buried pattern 210 and a second buried pattern 220 may be formed in a second opening 215. A U-shaped semiconductor pattern 205 may be formed on the bottom and both sidewalls of the first buried pattern 210. A first mask 300 may be formed on a seventh insulating layer 127. For example, the first mask 300 may be formed by depositing a photoresist followed by patterning the photo resist to partially cover the second buried pattern 220.

Referring to FIG. 7B, insulating layers 120 and sacrificial layers 130 may be formed into a stair type structure. The stair type structure may be formed by sequentially increasing a mask width using the same or similar methods as described with reference to FIGS. 3A-3L. For example, a portion of the seventh insulating layer 127 may be etched by an etch process using the first mask 300 as an etch mask to expose the sixth sacrificial layer 136. A first spacer 302s may be formed on a sidewall of the first mask 300 to form a second mask 310 which is wider than the first mask 300. The first spacer 302a may be formed by, for example, a polymer deposition and polymer etch that is the same or similar as described with reference to FIGS. 3C-3D. The first spacer 302s may be formed into spacer shape on the sixth sacrificial layer 136. The first spacer 302s may cover a portion of the second buried pattern 220 which is not covered by the first mask 300. The sixth sacrificial layer 136 and the sixth insulating layer 126 may be partially removed using the second mask 310 as an etch mask to expose the fifth sacrificial layer 135. The mask width increasing method and the etch process may be alternately performed to form the insulating layers 120 and the sacrificial layers 130 into a stair type structure. According to example embodiments, the sixth sacrificial layer 136 from the sacrificial layers of the stair type structure may be separated into three parts by the second opening 215. Similarly, the seventh insulating layer 127 and the sixth insulating layer 126 from the insulating layers 120 of the stair type structure may be separated into three parts by the second opening 215.

Referring to FIG. 7C, a trench 230 may be formed through the sacrificial layers 130 and the insulating layers 120. The semiconductor substrate 101 may be exposed in the trench 230. The trench 230 may be of the same or similar length to the second opening 215. The trench 230 may separate the sixth sacrificial layer 136 between adjacent two second openings 215 into two parts, respectively. Similarly, the trench 230 may separate the seventh insulating layer 127 and the sixth insulating layer 126 between adjacent two second openings 215. The sixth sacrificial layer 136 may be separated into four parts, and the sixth and seventh insulating layer 126 and 127 may be separated into four parts, respectively. According to example embodiments, the sacrificial layers 130 may be patterned into a stair type structure such that the sixth sacrificial layer 136 may be formed into separated line shapes and the first through fifth sacrificial layers 131-135 may be formed into a plate shape. The sixth sacrificial layer 136 may not be completely covered with the seventh insulating layer 127 but may be partially exposed.

Referring to FIG. 7D, the sacrificial layer 130 exposed in the trench 230 may be selectively removed to form recess regions 240 between the insulating layers 121 through 127. The semiconductor pattern 205 may be exposed in the recess regions 205. Referring to FIG. 7E, an information storage layer 250 and a gate 260 may be formed in the recess regions 240. The information storage layer 250 may include a charge storage layer, for example, a silicon nitride layer and/or a floating gate, between a tunnel insulating layer (not shown) and a blocking insulating layer (not shown). The gate 260 may be formed of polycrystalline silicon and/or metal formed in, for example, a deposition process. The trench 230 may be filled with the polycrystalline silicon and/or the metal. The polycrystalline silicon and/or the metal filling the trench 230 may be removed and a silicon oxide layer, a silicon nitride layer or their combination may be filled in the trench 230 to form a third buried pattern 267. A bit line pad 290 may be selectively formed as shown in FIG. 6L and a bit line 231 and a metal line 233 may be formed as shown in FIG. 6M to form a non-volatile memory device 1c (not shown).

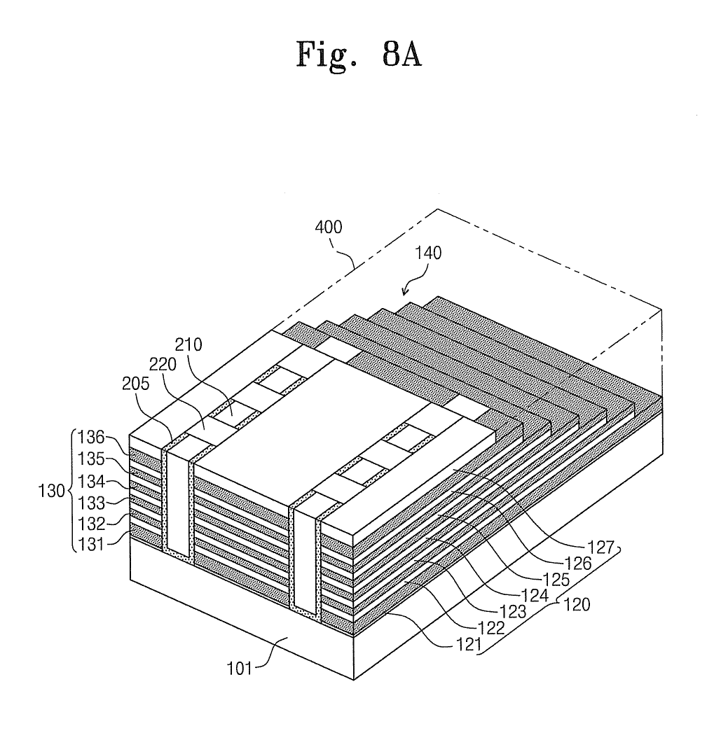

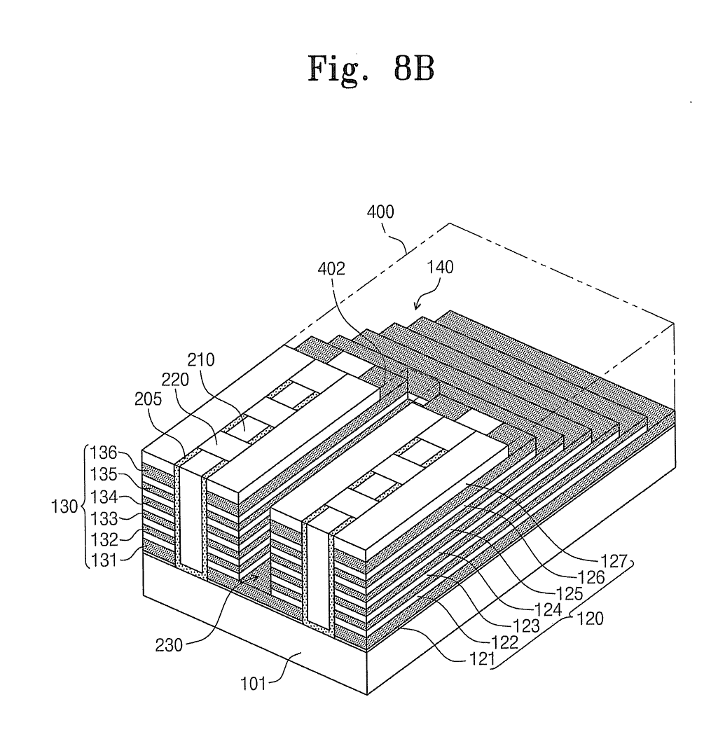

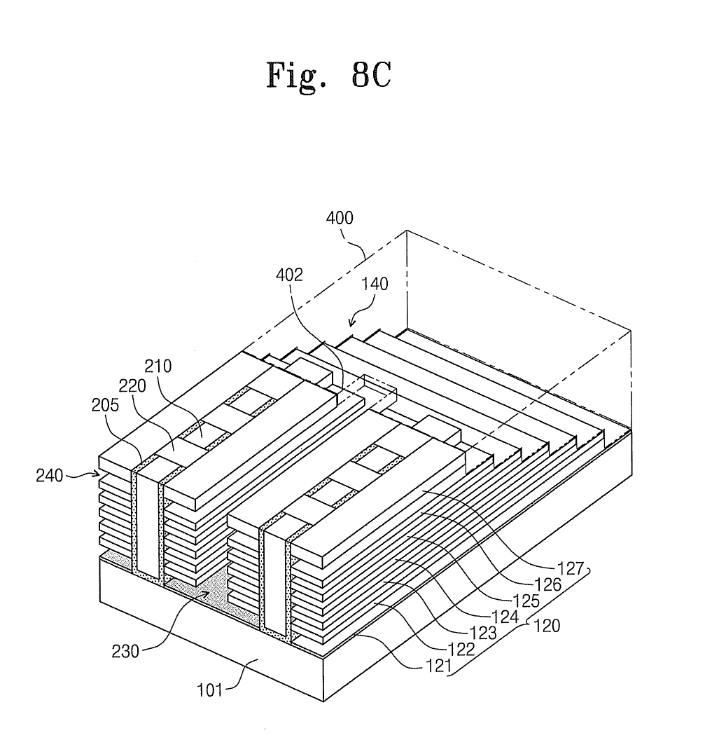

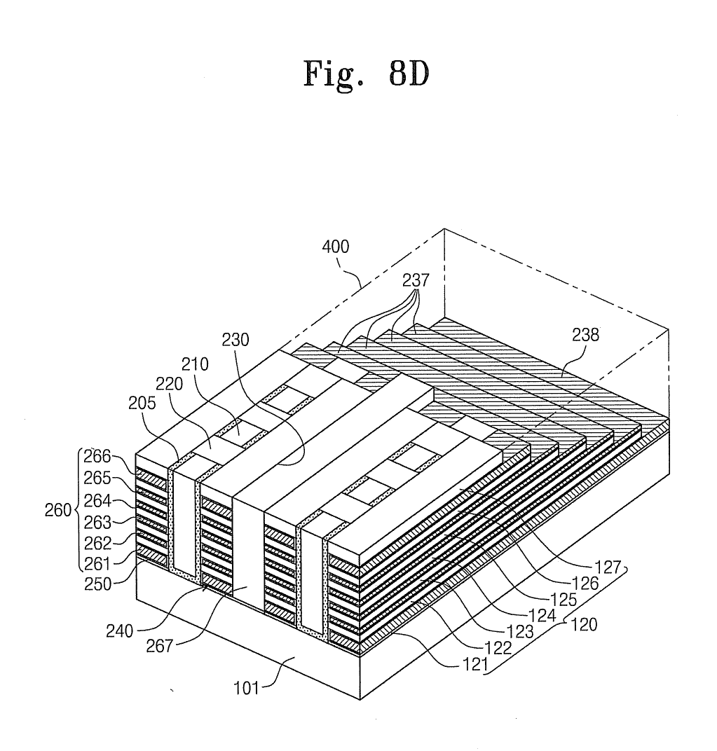

According to example embodiments of the inventive concepts, the gate 260 may replace the sacrificial layers 130 of stair type structure as shown in FIG. 7E. A method of dividing upper selection gates 266 may not be necessary during the gate forming process. Word line pads 237 may be formed on respective control gates 262-266, and a lower selection line pad 238 may be formed on the lower selection gate 261. The gate 260 may be a stair type structure on two sides as shown in FIG. 3L, and/or any be a stair type structure on one side as shown in FIG. 4C, and/or may be a pyramid structure as shown in FIG. 5C. The gate 260 of a stair type structure may be formed by the same or similar methods described with reference to FIGS. 8A-8D.

FIGS. 8A-8D are perspective views illustrating methods of manufacturing stair-type gate of the nonvolatile memory device according to example embodiments of the inventive concepts. Referring to FIG. 8A, the insulating layers 120 and the sacrificial layers 130 may be formed into a stair type structure by the method described with reference to FIG. 7B followed by forming a mask 400 which may cover a stair type structure portion 140. The mask 400 may be formed of, for example, a photoresist. Referring to FIG. 8B, a trench 230 may be formed by the method described with reference to FIG. 7C. The trench 230 may extend into the mask 400. A portion of the mask 400 may be removed to form a depressed region 402 while forming the trench 230.

Referring to FIG. 8C, the sacrificial layers 130 may be selectively removed to form recess regions 240 by the method describe with reference to FIG. 7D. The recess regions 240 may be closed by the mask 400. The recess regions 240 may be closed to the stair type pattern portion 140 while being open in the opposite direction. Referring to FIG. 8D, an information storage layer 250 and a gate 260 may be formed in the recess regions 240. If polycrystalline silicon and/or metal is formed in the recess regions 240, gates 261-266 may be formed into a stair type structure. A method for dividing upper selection gates 266 may not be necessary during the gate 260 forming method. A word line pad 237 may be on each control gate 262-266 and a lower selection line pad 238 may be on the lower selection gate 261. The polycrystalline silicon and/or the metal filling the trench 230 may be removed, and an insulating layer may be deposited to fill the trench and form a third buried pattern 267. Because the depressed region 402 of FIG. 8C may be filled with the third buried pattern 267, the third buried pattern 267 may be formed to protrude out of the seventh insulating layer 127. The mask 400 may be etched by an ash process.

Using the above processes, the sacrificial layers 130 of plate shape may be patterned into a stair type structure and may be replaced with gates 260 of a stair type structure. The process for replacing the sacrificial layers 130 with the gates 260 using the mask 400 may be applied to form the stair type structures of, for example, FIGS. 3L and/or 4C, and/or the pyramid structure of FIG. 5C.

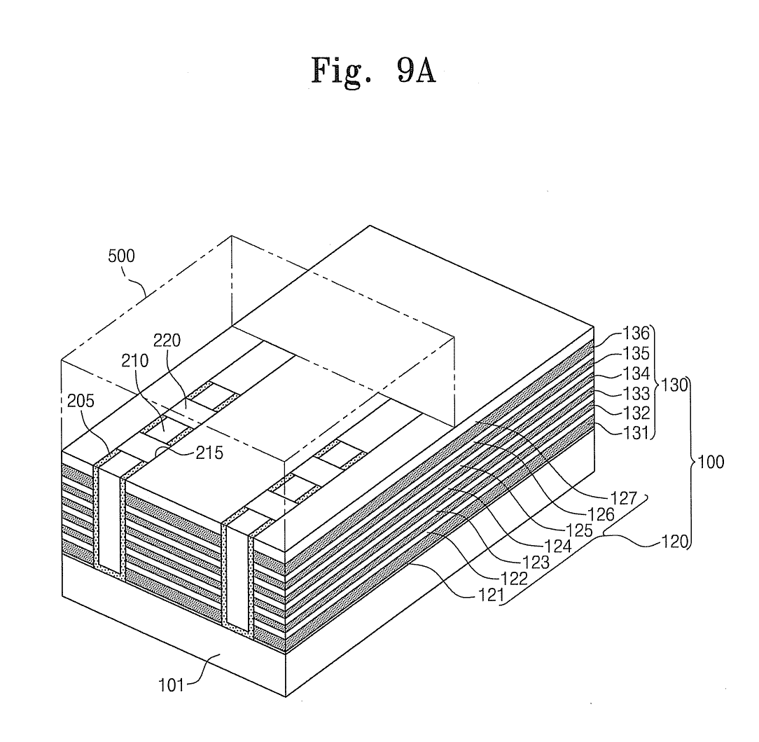

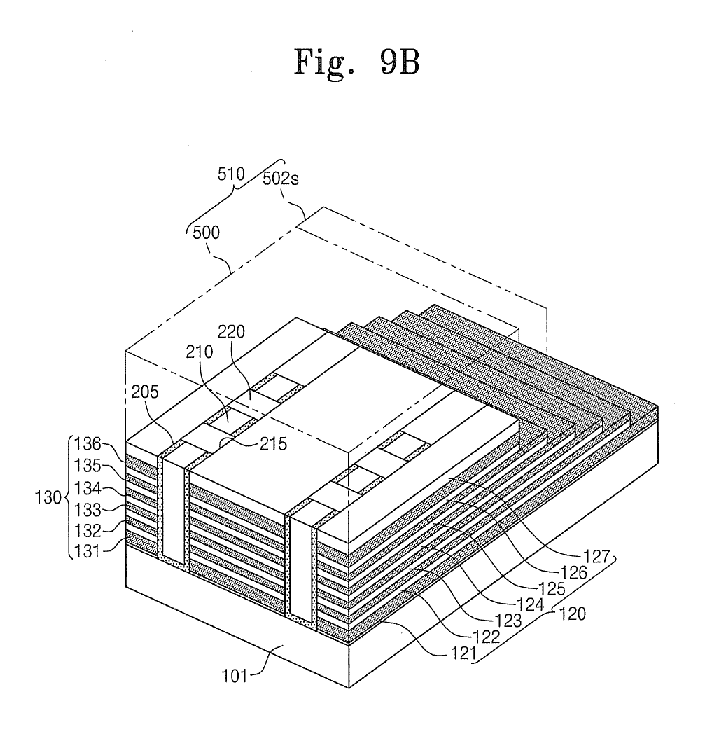

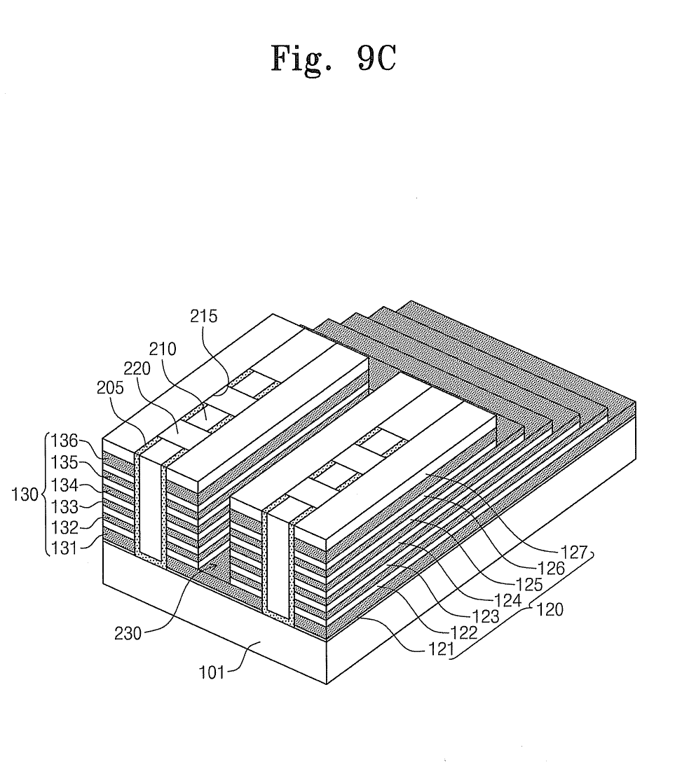

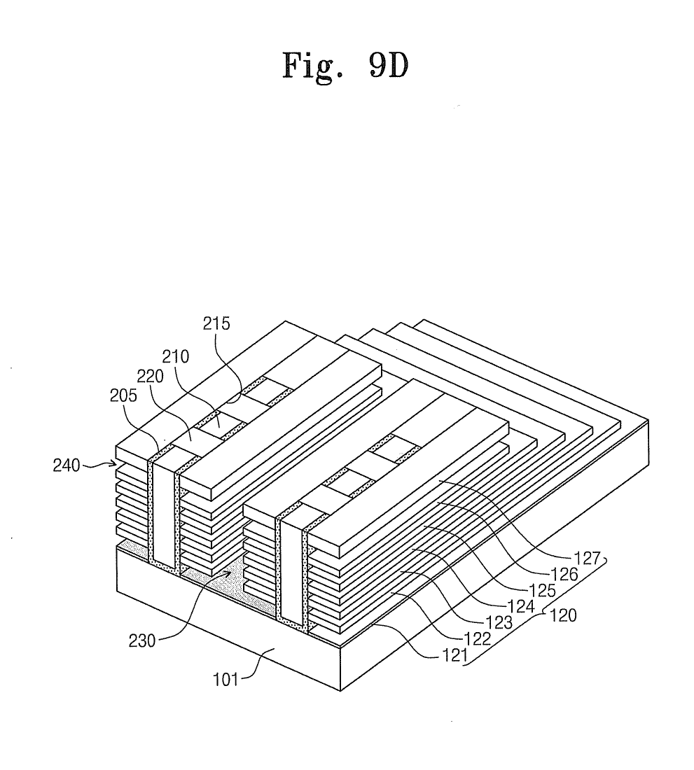

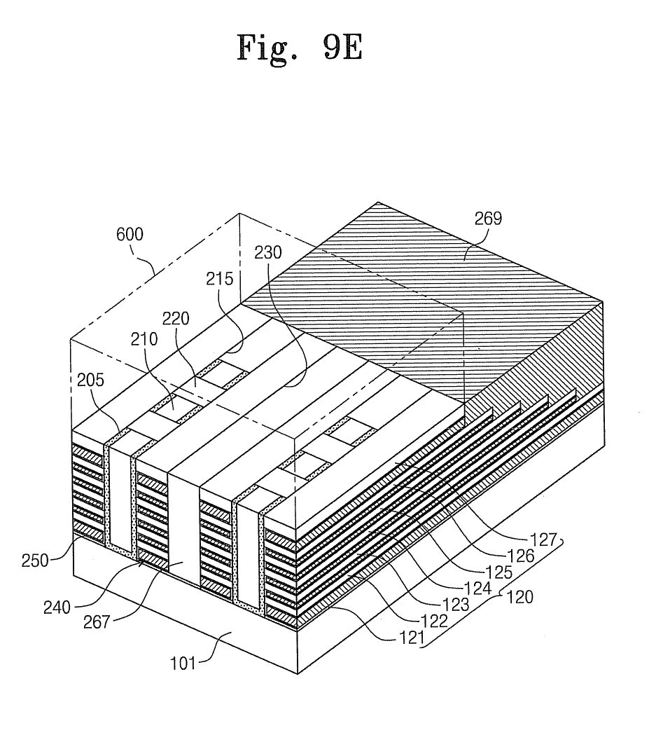

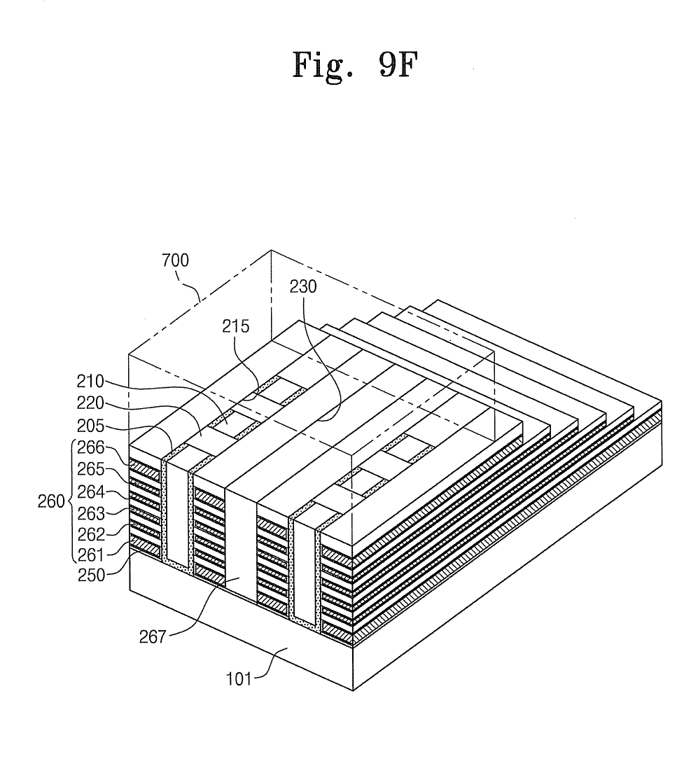

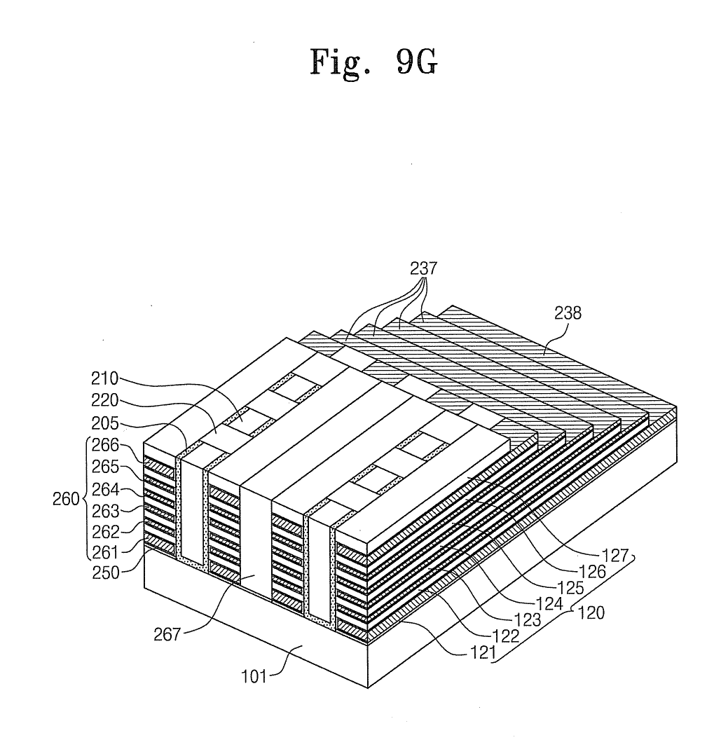

FIGS. 9A-9G are perspective views illustrating methods of manufacturing nonvolatile memory devices according to example embodiments of the inventive concepts. Features that may be similar to those described with respect to FIGS. 6A-6M may be omitted for brevity of description. Referring to FIG. 9A, insulating layers 121-127 and sacrificial layers 131-136 may be alternately stacked on the semiconductor substrate 101 to form a thin layer structure 100 using the same or similar methods as described with reference to FIGS. 6A-6C. A first buried pattern 210 and a second buried pattern 220 respectively with U-shaped semiconductor pattern 205 on both sidewalls may be formed in a second opening 215. A first mask 500 may be formed on the seventh insulating layer 127. The first mask 500 may be formed to cover the entire second buried pattern 220 by depositing a photoresist followed by patterning the photoresist.

Referring to FIG. 9B, portions of the seventh insulating layer 127 and the sixth sacrificial layer 136 may be removed by an etch process. The seventh insulating layer 127 and the sixth sacrificial layer 136 may be patterned into a plurality of lines which are divided by the second opening 215. A polymer deposition and a polymer etch, for example, may be performed in-situ as described with reference to FIGS. 3C and 3D. A first spacer 502s may be formed on the first mask 500 to form a second mask 510. The first spacer 502s may be formed on the fifth sacrificial layer 135. Portions of the fifth sacrificial layer 135 and the sixth insulating layer 126 may be removed by an etch process using the second mask 510 as an etch mask. The insulating layers 120 and the sacrificial layers 130 may be formed into stair type structure using the same or similar process as described with reference to FIGS. 3A-3L.

Referring to FIG. 9C, a trench 230 may be formed through the sacrificial layer 130 and the insulating layer 120 to expose the first sacrificial layer 131 and/or the semiconductor substrate 101. The trench 230 may be of the same or similar length to the length of the second opening 215. According to example embodiments, the sacrificial layer 130 may be patterned into a stair type structure such that the sixth sacrificial layer 136 may be formed into a plurality of lines, and the first through fifth sacrificial layers 131-135 may be formed into a stair type structure. Each of the first through fifth sacrificial layers 131-135 may be of a plate shape. The insulating layer 120 may be patterned into the same or similar structure as the sacrificial layer 130. The seventh insulating layer 127 may cover the entire sixth sacrificial layer 136.

Referring to FIG. 9D, the sacrificial layer 130 exposed by the trench 230 may be selectively removed to form recess regions 240 between the insulating layers 121-127. The semiconductor pattern 205 may be exposed by the recess regions 240. Referring to FIG. 9E, an information storage layer 250 and a conductive layer 269 may be formed in the recess regions 240. The conductive layer 269 may be formed of, for example, polycrystalline silicon and/or metal. The polycrystalline silicon and/or the metal may also fill the trench 230. The polycrystalline silicon and/or the metal filling the trench 230 may be removed by an etch process. A silicon oxide layer, silicon nitride layer or a combination thereof may fill the trench 230 to form a third buried pattern 267 filling the trench 230. The conductive layer 269 may be formed on a portion where the seventh insulating layer 127 does not cover. The first through the sixth insulating layers 121-126 may be covered with the conductive layer 269. A photoresist may be formed on the seventh insulating layer 127 to form a mask 600. The conductive layer 269 may be selectively removed by an etch process using the mask 600 as an etch mask. The mask 600 may be removed by an ash process.

Referring to FIG. 9F, the conductive layer 269 may be selectively etched to form a stair type structure. The upper selection gate 266 out of the gates 260 may be formed into a plurality of lines separated by the second opening 215. Control gates 262-265 and a lower selection gate 261 may be formed into a plate shape as part of a stair type structure. The gates 262-266 may be covered by the second through the seventh insulating layer 122-127 respectively. The gates 262-266 may not be exposed. A mask 700 may be formed on the seventh insulating layer 127. The mask 700 may not cover a portion of the second buried pattern 220. A photoresist may be deposited and patterned to form the mask 700. The second through the seventh insulating layer 122-127 may be selectively etched by an etch process using the mask 700 as an etch mask. The mask 700 may be removed by an ash process.

Referring to FIG. 9G, portions of the gates 261-266 may be exposed by the selective etch of the insulating layer 120. A word line pad 237 may be on each control gate 262-265 and a lower selection line pad 238 may be on the lower selection gate 261. The gates 260 may have a stair type structure on two sides as shown in FIG. 3L, stair type structure on one side as shown in FIG. 4C, and/or pyramid structure as shown in FIG. 5C. A bit line pad 290 may be selectively formed as shown in FIG. 6L, and a bit line 231 and a metal line 233 may be formed. A nonvolatile memory device 1c may be formed.

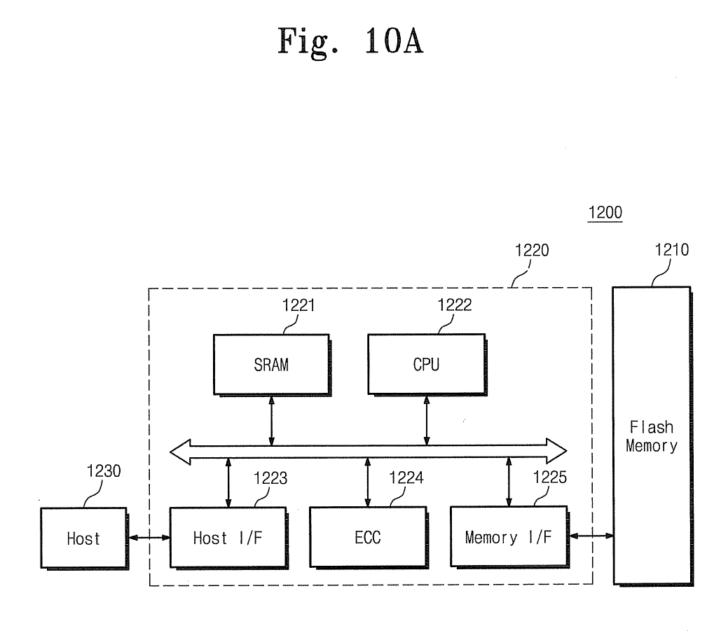

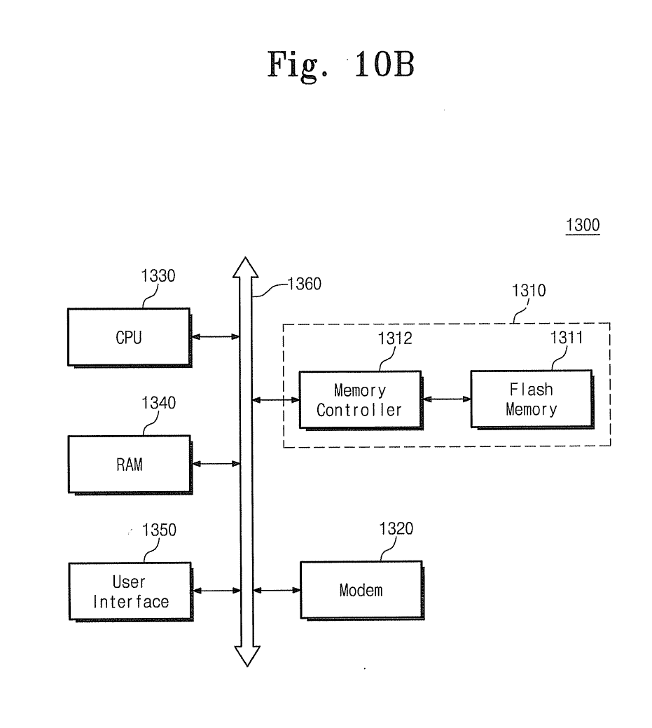

FIG. 10A is a block diagram illustrating memory cards including nonvolatile memory devices according to example embodiments of the inventive concepts. Referring to FIG. 10A, a memory card 1200 may include a flash memory 1210 in order to support high memory capacity. The flash memory 1210 may be a nonvolatile memory device, for example, a nonvolatile memory device described with respect to FIGS. 1A-9G. For example, the flash memory 1210 may be a vertical NAND flash memory device.

The memory card 1200 may include a memory controller 1220 which controls data exchange between a host 1230 and the flash memory 1210. An SRAM 1221 may be used as a driving memory for a central processing unit (CPU) 1222. A host interface 1223 may include data exchanging protocol of the host 1230 which is connected to the memory card 1200. An error collection code (ECC) 1224 may be capable of detecting and collecting errors in the data out of the flash memory 1210. A memory interface 1225 may interface with the flash memory 1210. The CPU 1222 may perform various control operations for data exchange operations of the memory controller 1220. Not shown in the drawing, the memory card 1200 may further include a ROM (Read Only Memory) which contains code data for interfacing with the host 1230.

FIG. 10B is a block diagram of information processing systems including nonvolatile memory devices according to example embodiments of the inventive concepts. Referring to FIG. 10B, a data processing system 1300 may include a flash memory system 1310 which may include a nonvolatile memory device, for example, a nonvolatile memory device described with respect to FIGS. 1A-9G. The flash memory device 1311 may be a vertical NAND flash memory device. A memory controller 1312 may control data exchange operations of the flash memory system 1310. The data processing system 1300 may include the flash memory system 1310, and a modem 1320, a CPU 1330, a RAM 1340 and a user interface 1350 which are electrically connected to system bus 1360. The flash memory system 1310 may store data processed by the CPU or input from the exterior.

The data processing system 1300 may be provided as, for example, a memory card, a solid state disk (SSD), a camera image sensor (CIS) and/or application chipsets. For example, the flash memory system 1310 may be provide as a SSD such that the data processing system 1310 can store a large amount of data stably and reliably in the flash memory system 1310.

According to example embodiments of the inventive concepts, a spacer may be formed on a sidewall of a mask such that a control gate may be formed in a stair-type structure. If, for example, the spacer is formed of a polymer, the process may be simplified and/or improved and process errors may be minimized and/or reduced because an in-situ process may be available. Thereby, manufacturing costs may be reduced.

While example embodiments have been particularly shown and described, it will be understood by one of ordinary skill in the art that variations in form and detail may be made therein without departing from the spirit and scope of the claims.

What is claimed is:

1. A method of manufacturing a stair-type structure, comprising:
stacking a plurality of thin layers;
forming a mask on the plurality of thin layers;
patterning at least one of the plurality of thin layers using the mask as an etch mask; and
sequentially increasing a width of the mask and patterning a different one of the plurality of thin layers such that each of the plurality of thin layers is patterned using a different width of the mask, the patterned plurality of thin layers forming a stair-type structure.

2. The method of claim 1, wherein each sequential increase of the width of the mask includes forming a pre-spacer layer to cover the mask, and
etching the pre-spacer layer to form a spacer as at least one sidewall of the mask.

3. The method of claim 2, wherein the forming of the pre-spacer layer includes providing a first gas with at least one deposition element and at least one etching element to deposit a polymer layer.

4. The method of claim 3, wherein the etching of the pre-spacer layer to form the spacer includes providing a second gas to remove a portion of the polymer layer.

5. The method of claim 4, wherein the foaming of the pre-spacer layer includes providing the first gas so that an atomic ratio of the at least one deposition element to the at least one etching element is greater than 1.

6. The method of claim 5, wherein the etching of the pre-spacer layer includes providing the second gas so that an atomic ratio of the at least one etching element to the at least one deposition elements is greater than 1, and
the forming of the pre-spacer layer and the etching of the pre-spacer layer are performed in-situ.

7. The method of claim 6, wherein the at least one deposition element includes at least one of carbon and carbon/hydrogen, and
the at least one etching element includes fluorine.

8. The method of claim 6, wherein the first gas includes methyl fluoride (CH₃F), and
the second gas includes one of trifluoromethane (CHF₃) and carbon tetrafluoride (CF₄).

9. The method of claim 8, wherein the second gas includes oxygen (O₂).

10. The method of claim 1, wherein each of the plurality of thin layers includes a plurality of different material layers, and
the stacking of the plurality of thin layers includes alternating deposition of the different material layers.

11. A method of manufacturing a stair-shaped structure, comprising:
stacking a plurality of conductive layers;
forming a mask on the plurality of conductive layers;
depositing a polymer layer to cover the mask by providing a gas including at least one deposition element and at least one etching element, an atomic ratio of the at least one deposition element to the at least one etching element being greater than 1;
transforming the polymer layer into a polymer spacer by providing a gas including the at least one deposition element and the at least one etching element, an atomic ratio of the at least one etching element to the at least one deposition element being greater than 1;
sequentially performing the depositing of the polymer layer and the transforming of the polymer layer a plurality of times to sequentially increase a width of the mask; and
patterning each of the plurality of conductive layers using a different width of the mask.

12. The method of claim 11, wherein the polymer spacer is formed on one of a sidewall, two sidewalls and four sidewalls of the mask.

13. The method of claim 11, wherein the forming of the mask includes forming at least one of a first photoresist pattern crossing over a center of a one of the plurality conductive layers closest to the mask, a second photoresist pattern covering a side region of a top surface of the one of the plurality of conductive layers, and a third photoresist pattern on a central region of the one of the plurality of conductive layers and surrounded by edge portions of the one of the plurality of conductive layers.

14. The method of claim 13, wherein the at least one of the first through third photoresist patterns is the first photoresist pattern,
the polymer layer is transformed into the polymer spacer so that the polymer spacer is on two sidewalls of the first photoresist pattern, and
a stair-type structure is formed at two side regions of the conductive layers.

15. The method of claim 13, wherein the at least one of the first through third photoresist patterns is the second photoresist pattern,
the polymer layer is transformed into the polymer spacer on one sidewall of the second photoresist pattern, and
a stair-type structure is formed at one side region of the conductive layers.

16. The method of claim 13, wherein the at east one of the first through third photoresist patterns is the third photoresist pattern,
the polymer layer is transformed into the polymer spacer on four sides of the third photoresist pattern, and
a stair-type structure is formed at four side regions of the conductive layers.

17. The method of claim 11, wherein the depositing of the polymer layer includes a deposition process using a first plasma,
the first plasma includes argon (Ar), nitrogen (N₂) and methyl fluoride (CH₃F),
the at least one deposition element includes carbon, and
the at least one etching element includes fluorine.

18. The method of claim 17, wherein the transforming of the polymer layer into the polymer spacer includes a dry etch process using a second plasma,
the second plasma includes argon (Ar), nitrogen (N₂), oxygen (O₂) and one of trifluoromethane (CHF₃) and carbon tetrafluoride (CF₄),
the at least one deposition element includes carbon,
the at least one etching element includes fluorine, and
the depositing of the polymer layer and the transforming of the polymer layer are performed in-situ.

19. The method of claim 11, further comprising:
forming a plurality of insulating layers between the plurality of conductive layers; and
patterning each of the plurality of insulating layers using a different width of the mask.

20. A method of manufacturing a nonvolatile memory device, comprising:
forming a lower selection gate on a semiconductor substrate;
forming a plurality of control gates in a stair-type structure on the lower selection gate, the forming of the plurality of control gates including
stacking a plurality control gate layers,
forming a mask on the plurality of control gate layers,
patterning a one of the plurality of control gate layers closest to the mask by using the mask as an etch mask, and
patterning each of the control gate layers after the control gate layer closest to the mask by sequentially increasing a width of the mask, each of the plurality of control gate layers patterned using a different width of the mask, the patterning of the control gate layers forming the stair-type structure such that a portion of each of the plurality of control gates is a word line pad;
forming an upper selection gate on the plurality of control gates; and
forming an active pillar penetrating through the plurality of control gates, the active pillar formed to connect to the semiconductor substrate.

21. The method of claim 20, wherein the sequentially increasing the width of the mask includes providing a first gas including at least one deposition element and at least one etching element to form a polymer layer covering the mask; and
providing a second gas including the at least one deposition element and the at least one etching element to remove a portion of the polymer layer to form a polymer spacer on at least one sidewall of the mask.

22. The method of claim 21, wherein the providing of the second gas to form the polymer spacer is performed in-situ with the providing of the first gas to form the polymer layer, and
an atomic ratio of the at least one deposition element and the at least one etching element is different between the providing of the first gas and the providing of the second gas.

23. The method of claim 22, wherein a quantity of the at least one deposition element is greater than a quantity of the at least one etching element in the first gas, and
a quantity of the at least one etching element is greater than a quantity of the at least one deposition element in the second gas.

24. The method of claim 21, wherein the at least one deposition element includes carbon (C), and
the at least one etching element includes fluorine (F).

25. The method of claim 21, wherein the providing of the first gas to form the polymer layer includes a deposition process using plasma,
the plasma includes argon (Ar), nitrogen (N₂) and methyl fluoride (CH₃F),
the at least one deposition element includes carbon, and
the at least one etching element includes fluorine.

26. The method of claim 21, wherein the providing of the second gas to form the polymer spacer includes a dry etch process using plasma,
the plasma includes argon (Ar), nitrogen (N₂), and one of the trifluoromethane (CHF₃) and carbon tetrafluoride (CF₄),
the at least one deposition element includes carbon, and
the at least one etching element includes fluorine.

27. The method of claim 26, wherein the plasma includes oxygen (O₂).

28. A method of manufacturing a nonvolatile memory device, comprising:
alternately stacking a plurality of insulating layers and a plurality of sacrificial layers on a semiconductor substrate to form a thin layer structure including a plurality of thin layers;
forming a mask on the thin layer structure;
patterning each of the plurality of thin layers by sequentially increasing a width of the mask so that each of the plurality of thin layers is etched using the mask at a different width as an etch mask, the patterning of the plurality of thin layers forming a stair-type structure;
selectively removing the plurality of sacrificial layers to form a plurality of recess regions between the insulating layers; and
filling the recess regions with conductive layers to form gates stacked in the stair-type structure.

29. The method of claim 28, wherein the patterning of the plurality of thin layers by sequentially increasing the width of the mask includes providing a gas including at least one deposition element and at least one etching element to deposit a polymer layer covering the mask, and etching the polymer layer in-situ with the depositing of the polymer layer to form a polymer spacer on at least one sidewall of the mask,
an atomic ratio of the at least one deposition element to the at least one etching element in the providing of the gas to deposit the polymer layer is greater than 1, and
an atomic ratio of the at least one etching element to the at least one deposition element in the etching of the polymer layer is greater than 1.

30. The method of claim 29, wherein the providing of the gas to deposit the polymer layer includes using plasma including methyl fluoride (CH₃F), and
the etching of the polymer layer includes using plasma including one of trifluoromethane (CHF₃) and carbon tetrafluoride (CF₄).

31. The method of claim 28, wherein the selectively removing the plurality of sacrificial layers to foam a plurality of recess regions includes removing a portion of the thin layer structure to form a trench in which one of the semiconductor substrate and an insulating layer closest to the substrate is exposed, and
the selectively removing the plurality of sacrificial layers includes providing an etchant to the thin layer structure through the trench.

32. A patterning method, comprising:
stacking a plurality of layers;
forming a first mask on the plurality of layers;
patterning a first layer of the plurality of layers using the first mask;
increasing a width of the first mask to form a second mask; and
patterning a second layer of the plurality of layers using the second mask.

33. The patterning method of claim 32, further comprising:
increasing a width of the of the second mask to form a third mask; and
patterning a third layer using the third mask,
wherein the plurality of layers is three or more layers.

34. A method of manufacturing a nonvolatile memory device, the method comprising the patterning method of claim 32.
